(19) United States
(12) Patent Application Publication
(10) Pub. No.: US 2021/0384258 A1
(43) Pub. Date: Dec. 9, 2021

(54) THREE-DIMENSIONAL RESISTIVE SWITCHING MEMORY DEVICE AND METHOD OF FABRICATING THE SAME

(71) Applicant: Seoul National University R&DB Foundation, Seoul (KR)

(72) Inventor: Cheol Seong Hwang, Seoul (KR)

(73) Assignee: Seoul National University R&DB Foundation, Seoul (KR)

(21) Appl. No.: 16/892,308

(22) Filed: Jun. 4, 2020

(30) Foreign Application Priority Data
Jun. 4, 2020 (KR) 10-2019-0065931

(51) Int. Cl. H01L 27/24; H01L 29/786; H01L 45/00; H01L 29/66

(52) U.S. Cl. CPC H01L 27/2454; H01L 29/7869; H01L 45/1608; H01L 45/146; H01L 29/66969; H01L 45/08

(57) ABSTRACT

The present invention relates to a three-dimensional resistive switching memory device including a plurality of memory cells. A three-dimensional resistive switching memory device according to an embodiment comprises a plurality of memory cells. Each memory cell comprises, a semiconductor channel layer comprising a metal oxide extended in a vertical direction on the substrate; a variable resistance layer contacting one side of the semiconductor channel layer and extended in the vertical direction; and a plurality of gate structures having a gate electrode disposed on the other side opposite to the one side of the semiconductor channel layer and defining the plurality of memory cells serially connected to each other along the vertical direction, and a gate insulating film arranged between the gate electrode and the semiconductor channel layer.

### CROSS-REFERENCES TO RELATED APPLICATION

The present application claims the benefit of Korean application number on 10-2019-0065931, filed on Jun. 4, 2019, which is herein incorporated by reference in its entirety.

### BACKGROUND OF THE INVENTION

### 1. Field

The present invention relates to semiconductor technology, and more particularly, to a three-dimensional resistive switching memory device and a method of fabricating the same.

### 2. Description of the Related Art

Next-generation memories have emerged as new resistive switching memory devices to replace flash memory which is a conventional resistive switching memory device. As one of the next-generation memories, a resistive random access memory (RRAM) has advantages such as low cost, simple structure, and fast read/write speed, and excellent durability. In addition, in a case of using a cross-point structure for the RRAM, a large-capacity memory device can be implemented, and in this view, research on the RRAM has been actively conducted.

In general, the degree of integration of a semiconductor memory device is an important factor in determining a product price. Accordingly, the demand for improving the integration degree of semiconductor memory devices becomes intensifying. Typically, the degree of integration of a semiconductor memory device is largely influenced by the level of fine pattern formation technology, since the degree of integration of the semiconductor memory device is mainly determined by a plane area occupied by the unit memory cells. However, as a higher level of miniaturization technology is required, there is a limit in improving the density due to the difficulty of semiconductor fabricating facilities and/or semiconductor fabricating processes, and the increase in storage capacity is also reaching a physical limit.

In particular, when a cross-point structure is used to implement a high-density memory device, the reliability and durability of the memory device are deteriorated due to an operating error caused by a cell cross-talk such as a leakage current generated during a read/write process of information or a low retention characteristic, and therefore, it becomes difficult to produce a high-performance memory. Therefore, a selection device is required for the implementation of the memory devices, and improvement of the degree of integration may be limited by the performance of the selection element. Therefore, a design, which is capable of highly integrating the selection device as well as the memory device, is required for high integration of the memory devices.

With regard to power consumption of the semiconductor memory device, it is preferable that the memory devices are driven with low power. However, when the intensity of the voltage to be applied to change the resistance of the memory device is large or the charge mobility inside the memory device is significantly low, there occurs a problem that excessive power consumption is required to drive the memory device.

The problem to be solved by the present invention is to meet the demand for high integration of a resistive switching memory device, by applying a selection device to a three-dimensional resistive switching memory device which high integration may be implemented by virtue of a simple structure with high reliability and durability, so that the operating errors may be reduced. In addition, in order to implement a memory device that may be driven with low power, it is possible to provide a semiconductor memory device which may perform a read/write operation with a low voltage, and has improved charge mobility of constituent materials.

Another problem to be solved by the present invention is to provide a method of fabricating three dimensional semiconductor device capable of easily and quickly fabricating a three-dimensional resistive switching memory device having the above-described advantages.

### SUMMARY OF THE INVENTION

A three-dimensional resistive switching memory device according to an embodiment of the present invention for solving the above problems comprises a plurality of memory cells. Each memory cell includes: a semiconductor channel layer comprising a metal oxide extended in a vertical direction on the substrate; a variable resistance layer contacting one side of the semiconductor channel layer and extended in the vertical direction; a gate electrode disposed on the other side opposite to the one side of the semiconductor channel layer and defining a plurality of memory cells serially connected to each other along the vertical direction; and a gate insulating film arranged between the gate electrode and the semiconductor channel layer.

In one embodiment, the gate insulating film may be provided individually for each gate electrode along the semiconductor channel layer, and in another embodiment, the gate insulating film may be provided by a portion of a common gate insulating film extended along the semiconductor channel layer.

In one embodiment, the metal element of the metal oxide may include zinc (Zn), nickel (Ni), niobium (Nb), titanium (Ti), zirconium (Zr), hafnium (Hf), molybdenum (Mo), magnesium (Mg), cobalt (Co), iron (Fe), copper (Cu), aluminum (Al), manganese (Mn), or a combination thereof. The metal oxide may include indium-gallium-zinc oxide (IGZO), Indium-tin oxide (ZTO), or combinations thereof.

The three-dimensional resistive switching memory device according to an embodiment may further include a conductivity enhancement layer disposed between the semiconductor channel layer and the gate insulating layer, and extended in the vertical direction along the semiconductor channel layer, and the conductivity enhancement layer may have a conductivity greater than that of off-state of the metal oxide of the semiconductor channel layer. In another embodiment, the conductivity enhancement layer may have the same conductivity type as the metal oxide of the semiconductor channel layer. In addition, optionally, the conductivity enhancement layer may include indium-tin oxide (ITO), and the thickness of the conductivity enhancement layer may be in a range of 3 nm to 7 nm.

In one embodiment, the thickness of the semiconductor channel layer may be within a range of 10 nm to 60 nm, the semiconductor channel layer may have a cylindrical shape, and a core insulator may be inserted into the semiconductor channel layer to open a semiconductor pillar. In another embodiment, the semiconductor channel layer may have a straight structure or pipe-shaped bit cost scalable (BICs) structure or a combination structure thereof.

In one embodiment, the variable resistance layer may include a unipolar or bipolar switching material, and the variable resistance layer may include aluminum oxide (AlOₓ), zirconium oxide (ZrOₓ), titanium oxide (TiOx), and niobium oxide (NbOx), Nickel oxide (NiOx), zinc oxide (ZnOx), manganese oxide (MnOₓ) tungsten (W) oxide (AlOₓ), tantalum oxide (TaOₓ) or hafnium oxide (HfOₓ). In other embodiments, the variable resistance layer may include TiO₂, and an oxygen vacancy filament may be formed or destroyed inside the variable resistance layer according to an electric field, so that the resistance of the variable resistance layer may be adjusted.

In one embodiment, in each of the plurality of memory cells, the semiconductor channel layer and the variable resistance layer may be connected in parallel. A turn-off voltage is applied to a gate electrode of a selected memory cell among the plurality of memory cells, and a turn-on voltage is applied to gate electrodes of unselected memory cells among the plurality of memory cells. A three-dimensional resistive switching memory device which stores a piece of information by changing the size of the resistance of the variable resistance layer of the selected memory cell by changing the voltage applied across both ends of the semiconductor channel layer and the variable resistance layer which are in a parallel manner connected may be provided.

In another embodiment, the dual channel layer including the semiconductor channel layer and the conductivity enhancement layer, and the variable resistance layer may be connected in parallel. In another embodiment, a turn-off voltage is applied to the gate electrode of the selected memory cell among the plurality of memory cells, and a turn-on voltage is applied to the gate electrodes of the non-selected memory cells of the plurality of memory cells. In the unselected memory cells to which the turn-off voltage is applied, the current flows through the dual channel layer, and in the selected memory cell to which the turn-off voltage is applied, the electric charges of the conductivity enhancement layer move to the semiconductor channel layer. As a result of it, the resistance of the dual channel layer increases, and thus, the current signal flowing in the dual channel layer, and a piece of information may be stored by changing the size of the resistance of the variable resistance layer of the selected memory cell.

A three-dimensional resistive switching memory device according to an embodiment for solving the above problems may be provided, which is characterized in that it comprises, memory strings each including a plurality of memory cells connected in series; word lines connected to gate electrodes of the plurality of memory cells; bit lines connected to one end of each of the memory strings; source lines connected to the other end of each of the memory strings; a row decoder electrically connected to the plurality of memory cells through the word lines; and a column decoder electrically connected to the plurality of memory cells through the bit lines, and the plurality of memory cells are spaced apart in a first direction on the substrate and in a second direction different from the first direction, and vertically extended with respect to the substrate, and are formed along a common semiconductor layer, and each memory cell further comprises, a semiconductor channel layer including a metal oxide extended in a vertical direction on a substrate; a variable resistance layer which is in contact with one side of the semiconductor channel layer, and extends in the vertical direction; a plurality of gate structures consisting of a gate electrode disposed on the other side opposite to the one side of the semiconductor channel layer and defining a plurality of memory cells serially connected to each other along the vertical direction, and a gate insulating layer between the gate electrode and the semiconductor channel layer; and a conductivity enhancement layer disposed between the semiconductor channel layer and the gate insulating layer and extended in the vertical direction along the semiconductor channel layer, and the conductivity enhancement layer has a conductivity greater than that of the off-state conductivity of the metal oxide of the semiconductor channel layer.

The metal oxide may include indium-gallium-zinc oxide (IGZO), indium-tin oxide (ITO), or a combination thereof, and the conductivity enhancement layer may include indium-tin oxide (ITO).

According to another embodiment of the present invention for solving the above problems, a method for driving a resistive switching memory device comprising a semiconductor channel layer including indium-gallium-zinc oxide (IGZO) or indium-tin oxide (ITO); memory strings each comprising a plurality of memory cells including a variable resistance layer and a conductivity enhancement layer comprising indium-tin oxide (ITO); word lines connected to a gate electrode of each of the plurality of memory cells; bit lines connected to one end of each of the memory strings; source lines connected to the other end of each of the memory strings; a row decoder electrically connected to the plurality of memory cells through the word lines; and a column decoder electrically connected to the plurality of memory cells through the bit lines is suggested. A method for driving three-dimensional resistive switching memory device comprising a step for applying a turn-off voltage to the selected word lines and for applying a turn-on voltage to the unselected word lines; a programming step including a step for applying a set voltage (Vset) or a reset voltage (Vreset) to the selected bit line to change the size of the resistance of the variable resistance layer of the selected memory cell, and a step for applying a third driving voltage to the selected word line and for applying a fourth driving voltage to the unselected word lines; and a reading step of applying a reading voltage to the selected bit line may be provided.

A method of fabricating a three-dimensional resistive switching memory device according to an embodiment of the present invention may comprise, a step for providing a substrate; a step for repeatedly and alternately stacking an insulating film and a conductive film on the substrate; a step for forming first holes which are spaced apart from each other in a first direction parallel to the substrate and in a second direction different from the first direction, and which are continuously and vertically penetrating through the repeatedly and alternately laminated the insulating film and the conductive film; a step for forming a gate insulating film on the inner sidewalls of the holes passing through penetrating the repeatedly and alternately the laminated insulating film and the conductive film; a step for forming a semiconductor channel layer including a metal oxide on the gate insulating film; a step for forming a variable resistance layer on the semiconductor channel layer; a step for forming a trench layer extended in the first direction and the vertical direction by patterning the repeatedly laminated insulating layer and the sacrificial layer in order to separate an interface between the semiconductor channel layers aligned in a second direction which is parallel to the substrate and is different from the first direction, and for forming a laminated structure of an insulating film pattern and a sacrificial film pattern through which the semiconductor channel layers pass; a step for removing the sacrificial film pattern of the laminated structure exposed through the trench region to form cell spaces where the upper surface of the semiconductor channel layers is exposed between the laminated insulating layer patterns; a step for forming a gate insulating film on the upper surface of the semiconductor channel layers exposed through the cell spaces; and a step for forming a conductive layer filling at least a portion of the cell spaces on which the gate insulating layer is formed. Optionally, the semiconductor channel layer may use In₂Ga₂ZnO₇ as a precursor.

In one embodiment, a method of fabricating a three-dimensional resistive switching memory device may further include a step for forming a conductivity enhancement layer after forming the first holes, and a step for annealing the semiconductor channel layer, a variable resistance layer, and the conductivity enhancement, and the annealing step may be performed at 300° C. to 400° C.

In another embodiment, a method of fabricating a three-dimensional resistive switching memory device may comprise, a step for providing a substrate; a step for repeatedly and alternately stacking an insulating film and a conductive film on the substrate; a step for forming first holes which are spaced apart from each other in a first direction parallel to the substrate, and in a second direction different from the first direction, and which are continuously and vertically penetrating through the repeatedly and alternately laminated the insulating film and the conductive film; a step for forming a gate insulating film on the inner sidewalls of the holes passing through penetrating the repeatedly and alternately the laminated insulating film and the conductive film; a step for forming a semiconductor channel layer including a metal oxide on the gate insulating film; and a step for forming a variable resistance layer on the semiconductor channel layer. Optionally, the semiconductor channel layer may use In₂Ga₂ZnO₇ as a precursor.

In one embodiment, a method of fabricating a three-dimensional resistive switching memory device may further include a step for forming a conductivity enhancement layer after forming a gate insulating layer on inner sidewalls of holes passing through the conductive layer, and a step for annealing the semiconductor channel, the variable resistance layer and the conductivity enhancement layer, and wherein the annealing may be performed at 300° C. to 400° C.

According to a three-dimensional resistive switching memory device according to an embodiment of the present invention, a unit memory in which a semiconductor channel layer capable of performing an on/off function, and a variable resistance layer are connected in parallel according to an electric field applied by a gate electrode is connected in series. Therefore, a three-dimensional resistive switching memory device having improved integration and high reliability and durability may be provided.

In addition, according to the three-dimensional resistive switching memory device according to an embodiment of the present invention, a three-dimensional resistive switching memory device that may be driven with low power may be provided by inserting a conductive material having high electric charge mobility inside the memory device.

Furthermore, according to a three-dimensional resistive switching memory device according to an embodiment of the present invention, a three-dimensional resistive switching memory device wherein mobility of oxygen ions into or out of the variable resistance layer is increased, and a read/write operation by formation and destruction of conductive filaments generated by movement of oxygen ions is realized may be provided, when using indium-gallium-zinc oxide (IGZO) as the semiconductor channel.

### BRIEF DESCRIPTION OF THE DRAWINGS

FIG. 1 is a block diagram illustrating a three-dimensional resistive switching memory device according to an embodiment of the present invention.

FIG. 2A and FIG. 2B are perspective views showing three-dimensional resistive switching memory devices including memory cells having a variable resistance layer according to an embodiment of the present invention.

FIG. 3A is an enlarged cross-sectional view showing the structure of a memory cell region indicated by a dotted circle in FIG. 2A according to an embodiment of the present invention, FIG. 3B is a memory cell region indicated by a dotted circle in FIG. 2B according to an embodiment of the present invention, FIG. 3C is an enlarged cross-sectional view showing a structure of a unit memory cell region of a three-dimensional non-volatile semiconductor memory device further including a conductivity enhancement layer according to an embodiment of the present invention, and FIG. 3D is an enlarged cross-sectional view showing the structure of the unit memory cell region of the three-dimensional non-volatile semiconductor memory device further including the conductivity enhancement layer according to the another embodiment of the present invention.

FIG. 4A is an IV measurement graph when indium-gallium-zinc oxide (IGZO) is utilized as an electrode of a variable resistance material according to an embodiment, and FIG. 4B is a schematic diagram showing the movement of the conductive filament (CF) and electrons under a low resistance state (LRS) of the variable resistance material, and FIG. 4C is a schematic diagram showing the movement of the conductive filament (CF) and electrons under a high resistance state (HRS) of the variable resistance material.

FIG. 5 is an electrical circuit diagram showing the electrical function of each part of the three-dimensional resistive switching memory devices according to an embodiment of the present invention.

FIG. 6A to FIG. 6K are cross-sectional views sequentially illustrating a method of fabricating a three-dimensional resistive switching memory device according to an embodiment of the present invention.

FIG. 7A to FIG. 7H is plan views sequentially illustrating a method of fabricating a three-dimensional resistive switching memory device according to an embodiment of the present invention.

FIG. 8A to FIG. 8H are cross-sectional views sequentially illustrating a method of fabricating a three-dimensional resistive switching memory device according to an embodiment of the present invention.

FIG. 9A to FIG. 9D are plan views sequentially illustrating a method of fabricating a three-dimensional resistive switching memory device according to an embodiment of the present invention.

### DETAILED DESCRIPTION OF THE INVENTION

Hereinafter, the preferred embodiments of the present invention will be described in detail with reference to the accompanying drawings.

The embodiments of the present invention are provided to more completely explain the present invention to those having a common knowledge in the related art, and the following embodiments may be modified into various other forms, and the scope of the present invention is not limited to the following embodiments. Rather, these embodiments are provided to completely convey the technological spirit of the present invention to those skilled in the art.

The same reference numbers in the drawings refer to the same elements. Also, as used herein, the term, “and/or” includes any one of the listed items, or any combination of one or more of the listed items.

The terminology used herein is used to describe the embodiments, and is not intended to limit the scope of the present invention. In addition, even though a singular form is described in this specification, the plural form may be included, unless the context clearly indicates the singular. Also, the terms, “comprise” and/or “comprising” as used herein specify the mentioned shapes, numbers, steps, operations, members, elements and/or presence or addition of these groups,

but does not exclude other shapes, numbers, operations, members, elements and/or presence or addition of these groups.

The reference herein to a layer formed “on” a substrate or other layer may refer to a layer formed directly above the substrate or other layer, or may refer to a layer formed on an intermediate layer or intermediate layers formed on the substrate or other layer. It may also refer to a layer. In addition, it should be understood to those skilled in the related art that a structure or shape disposed “adjacent” to another shape may have portions overlapping or disposed below the adjacent shape.

In this specification, the relative terms such as “below”, “above”, “upper”, “lower”, “horizontal” or “vertical” may be used to describe the relationship between one configuring member, layer or region and another configuring member, layer or region, as shown on the drawings. It should be understood that these terms encompass not only the directions indicated in the drawings, but also other directions of the device.

In the following descriptions, the embodiments of the present invention will be described with reference to cross-sectional views schematically showing ideal embodiments (and intermediate structures) of the present invention. In these drawings, for example, the size and shape of the members may be exaggerated for convenience and clarity of description, and in actual implementation, transformations of the illustrated shape may be expected. Accordingly, the embodiments of the present invention should not be construed as limited to the specific shapes of the regions shown herein. In addition, the reference numerals for members of the drawings refer to the same members throughout the drawings.

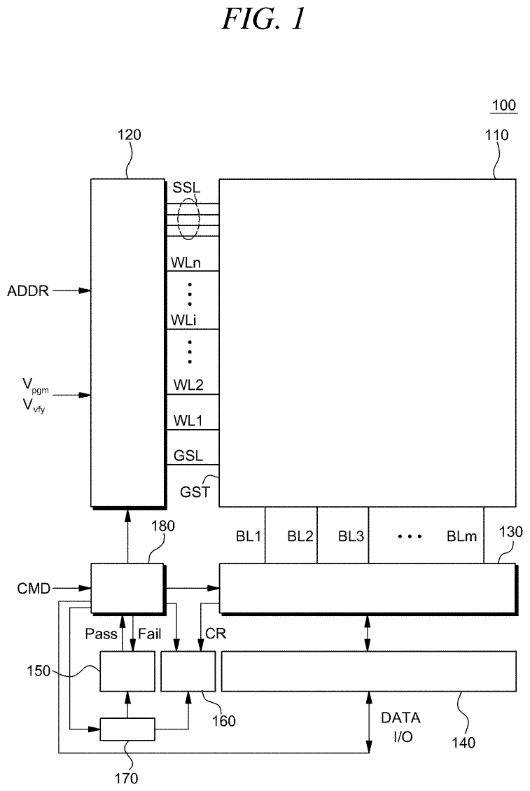

FIG. 1 is a block diagram illustrating a three-dimensional resistive switching memory device 100 according to an embodiment of the present invention.

Referring to FIG. 1, the three-dimensional resistive switching memory device 100 includes a memory cell array 110 of a plurality of memory cells, a row decoder 120, a read/write circuit 130, and a column decoder 140. The memory cell array 110 may be connected to the row decoder 120 through word lines WL1, WL2, . . . , WLi, . . . , WLn, selection lines SSL, and a ground line GSL. Also, the memory cell array 110 may be connected to the read/write circuit 130 through bit lines BL1, BL2, BL3, . . . , BLn.

In the case of the three-dimensional resistive switching memory device 100, the memory cell array 110 may include memory cell strings (not shown) in which a plurality of memory cells are connected in series. At least one or more string selection transistors may be connected to one end of the memory cell strings, and a ground selection transistor may be connected to the other end of the memory cell strings. A common source line may be connected to the other end of the memory cell string, and one end of the ground selection transistors may be electrically connected to the common source line. The word lines WL1, WL2, . . . , WLi, . . . , and WLn may be connected to control gates of memory cells arranged in a column direction, respectively. The bit lines BL1, BL2, BL3, . . . , and BLn may be connected to one end of the string select transistors.

A plurality of memory cells in a row direction coupled to each word line WL1, WL2, . . . , WLi, . . . , and WLn may configure a logical page, and the number of logical pages may be determined depending on the storage capacity of the memory cell. The memory cells configuring the page may be programmed in the same program cycle. For example, each memory cell connected to the first word line WL1 may be programmed to the same program state (or target value) or different program state in the same program cycle.

The row decoder 120 may select one or more string selection lines SSL. Also, the row decoder 120 may select any one of word lines of the memory block. The row decoder 120 may apply the word line voltage VWL received from the voltage generator (not shown) to the word lines of the selected memory block. During the programming operation, the row decoder 120 may apply a turn-off voltage to a selected word line and a turn-on voltage to an unselected word line. In order to avoid duplicate description, descriptions of the turn-off voltage and turn-on voltage will be described later

The memory cell array 110 may be addressed by the bit lines BL1, BL2, BL3, . . . , BLn through the column decoder 140. The read/write circuit 130 may receive data transmitted from the outside through the column decoder 140 or may output data to the outside.

The read/write circuit 130 may include a page buffer (not shown), and may operate as a sense amplifier or a write driver depending on the operation mode. However, in this specification, the terms, i.e., read/write circuit 130, and page buffer, are used as having an equivalent meaning, and should be understood as being compatible with each other. For example, during a programming operation, the read/write circuit 130 receives data from an external circuit and transmits a bit line voltage corresponding to data to be programmed into the bit line of the cell array 110. During the read operation, the read/write circuit 130 may read data stored in the selected memory cell through a bit line, and latch the read data to output to the outside.

The read/write circuit 130 may perform a verification operation accompanying a programming operation of a memory cell in response to a transmission signal transmitted from the control logic 180, and verify and may output a verification read result as a page buffer signal multiple times in response to the transmission signal. In one embodiment, the read operation of the read/write circuit 130 may use a charge integration using a bit line parasitic capacitor.

The control logic 180 may program the selected memory cell by executing program-verification loops according to an incremental step pulse programming (ISPP) mode. The pass/fail verification circuit 150 verifies whether the memory cell has reached a desired level whenever the program loop count increases. When the variable resistance layer of the memory cell has a desired resistance value, that is, a target value, it is determined as a program pass and the program and program verification operation for the memory cell are terminated. However, if the memory cell does not reach a desired resistance value, the pass/fail verification circuit 150 may determine it as the program failure and generate a count signal (not shown). The pass/fail verification circuit 150 may determine whether the program is successful and may transfer the result to the control logic 180.

The control logic 180 can control a row decoder 120, a read/write circuit 130, a column decoder 140, and a pass/fail detection circuit 150, a program loop sequence detector 160, and/or a comparator 170 in order to perform a pulse program and a verification operation based upon the ISPP method according to an instruction (CMD). The control logic 180 may determine whether to end or continue the programming operation by referring to the success or failure (Pass/Fail) of the program transmitted from the pass/fail detection circuit 150. When the result of the program fail is received from the pass/fail verification circuit 150, the control logic 180 will control the voltage generator (not shown) which generates a turn-off voltage and a turn-on voltage, and the page buffer (not shown) to proceed a subsequent program loop. As such, the control logic 180 may receive the sequence number of the program loop in order to progress the program according to the increasing number of program loops. Conversely, when the control logic 180 receives the result of the program pass, the programming operation for the selected memory cells will end.

In various designs, the control logic 180 may be integrated in the same chip as the memory cell array 110 or disposed on another chip, and the present invention is not limited thereto. For example, as in an SSD (solid state drive), the control logic 180 may also be provided in a flash translation layer (FTL), which is a separate chip separated from the memory cell array 110.

In addition, although the above-described pass/fail verification circuit 150, the program loop sequence detector 160, and the comparator 170 are illustrated separately formed from the control logic 180, the present invention is not limited thereto. For example, at least any one of the pass/fail verification circuit 150, the program loop sequence detector 160, and the comparator 170 may be implemented in software or hardware within the control logic 180. In addition, it is obvious that at least one of the pass/fail verification circuit 150, the program loop sequence detector 160 and the comparator 170 may be omitted or another circuit configuration may be added.

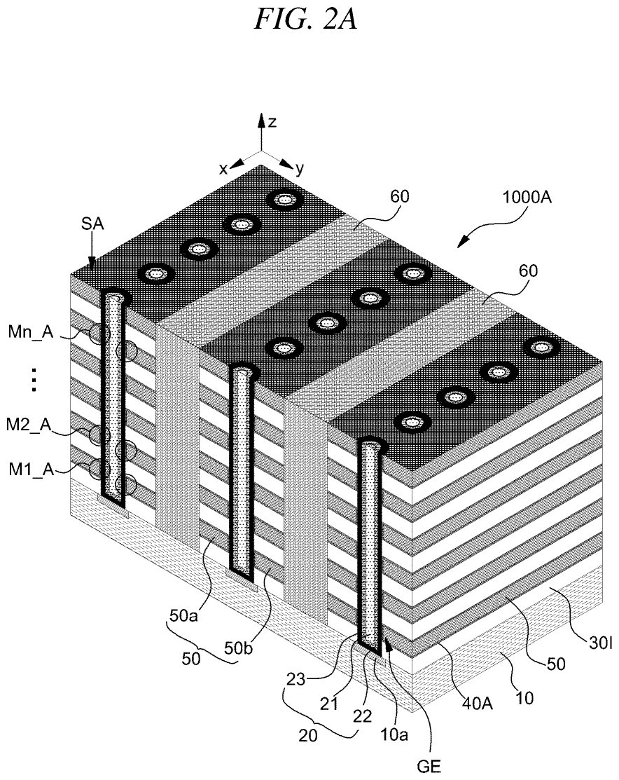

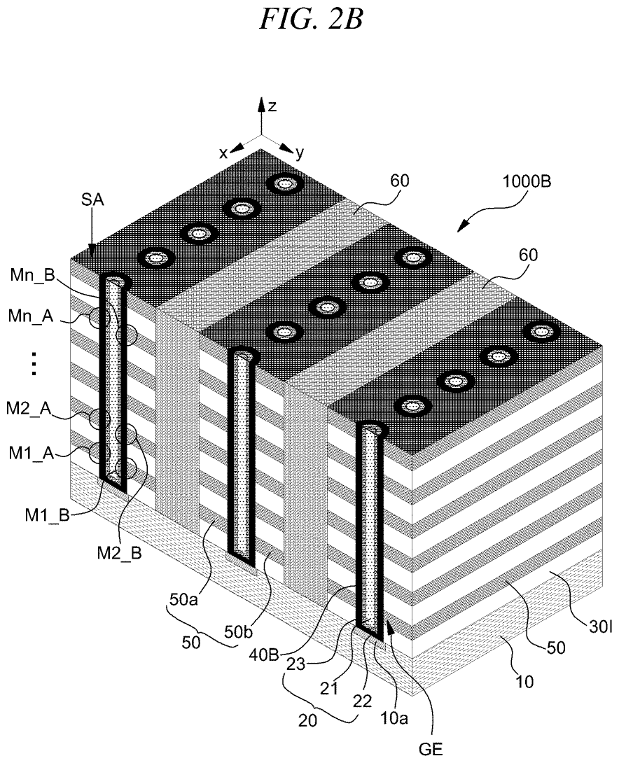

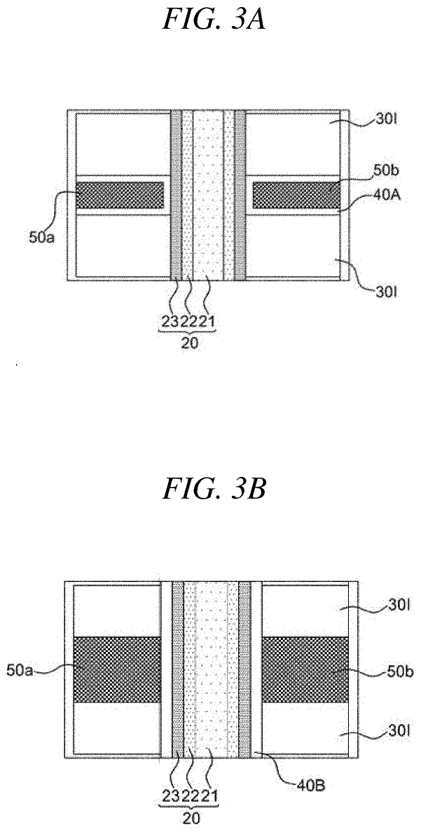

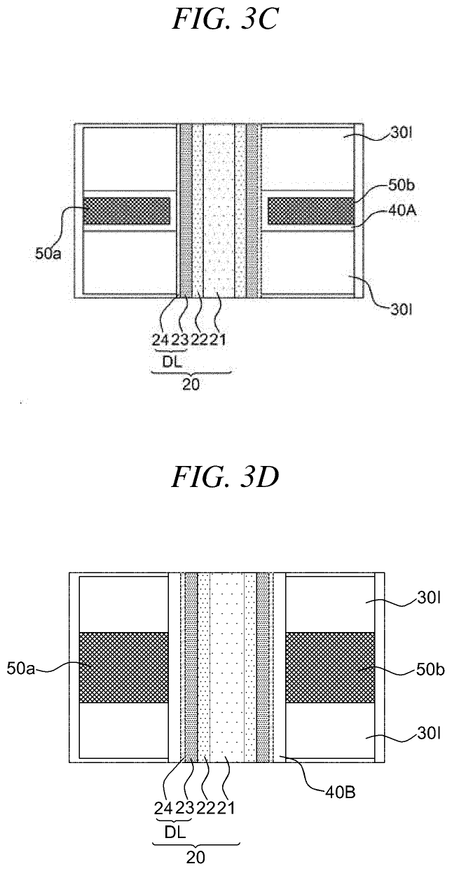

FIG. 2A and FIG. 2B are perspective views showing three-dimensional resistive switching memory devices 1000A and 1000B including memory cells M1_A, M2_A; . . . ; Mn_A having a variable resistance layer 22 according to an embodiment of the present invention. FIG. 3A is an enlarged cross-sectional view showing the structure of a memory cell region indicated by a dotted circle in FIG. 2A according to an embodiment of the present invention, and FIG. 3B is a memory cell region indicated by a dotted circle in FIG. 2B according to an embodiment of the present invention.

Referring to FIG. 2A, the three-dimensional resistive switching memory device 1000A may include a plurality of memory cells M1_A, M2_A; . . . ; Mn_A arranged in three-dimensional format, which are aligned in an x-direction (hereinafter referred to as a first direction) parallel to the substrate 10, and a y-direction different from the x-direction (Hereinafter, it is referred to as a second direction, in the z direction (hereinafter referred to as the vertical direction) perpendicular to the substrate 10. In some embodiments, the first direction (x direction) and the second direction (y direction) may be orthogonal to each other.

The substrate 10 may be a semiconductor substrate such as a silicon (Si) single crystal substrate, a chemical compound semiconductor substrate, a silicon on insulator (SOI) substrate, and a strained substrate. In one embodiment, a semiconductor layer may be formed in a peripheral circuit region defined under the three-dimensional resistive switching memory cell 1000A, and the semiconductor layer itself may be a substrate. The embodiment of the present invention is not limited to this. For example, in another embodiment, the substrate 10 may be a ceramic substrate or a polymer substrate for implementing a flexible device, or a fabric layer. The substrate 10 may be provided with a conductive member 10a such as an impurity region formed due to doping or a wiring such as a conductive film (not shown). The conductive member 10a may be the aforementioned source line to which one end of the memory string MS is coupled.

Semiconductor pillars 20 for providing channels to the plurality of memory cells M1_A, M2_A, . . . , and Mn_A may extend in a vertical direction (z direction) on the substrate 10. The semiconductor pillars 20 may include a core insulator 21, a variable resistance layer 22, and a semiconductor channel layer 23, and in another embodiment, may further include a conductivity enhancement layer 24. The configuring parts of the semiconductor pillars 20 may have a pillar structure composed of a plurality of layers with a common central axis, or may be a structure laminated on a flat plate, and the arrangement of the configurations is not limited, and may have various shapes.

The semiconductor pillars 20 may be arranged on the substrate 10 to be spaced apart in a first direction (x direction) and a second direction (y direction). The semiconductor pillars 20 may be extended in the first direction (x direction) and the third direction (z direction), and the pillars may be separated by a device separation insulating film 60 so that they may be spaced apart from each other in the second direction (y direction)

In one embodiment, each memory cell may include a semiconductor channel layer 23 including a metal oxide extended in a vertical direction on a substrate; a variable resistance layer 22 in contact with one side of the semiconductor channel layer 23 and extended in the vertical direction; and a plurality of gate structures consisting of a gate electrode 50 disposed on the other side opposite to the one side of the semiconductor channel layer 23 and defining a plurality of memory cells serially connected to each other along the vertical direction, and the gate insulating films 40A and 40B between the semiconductor channel layer 23.

Each of the memory cells may be arranged in the vertical direction to form memory strings MS. In the embodiment shown in FIG. 2A, in order to select each memory string MS, a selection transistor and/or a ground selection transistor coupled to the memory string MS are omitted, and in connection with this respect, a widely-known technology may be referred to. The memory cells of the memory string MS may be formed by any number, for example, the memory cells corresponding to any number selected from 32, 48, 64, 72, 96 and 128 may be formed, and the number may be appropriately selected in consideration of the required memory capacity, yield, and/or total resistance connected in series. The present invention is not limited thereto. The series-connected memory cells have a structure similar to a memory string MS of a NAND flash memory device, and thus may have one bit line junction. Accordingly, there is an advantage that parasitic capacitance is reduced as compared to a structure in which each memory cell is connected in parallel or has a bit line junction of each memory cell, such as a NOR type array, and sense current may be increased and the sensing margin may also be improved by such an advantage.

In one embodiment, the gate insulating film 40A may be provided individually for each gate electrode 50 along the semiconductor channel layer 23. For example, as in the three-dimensional resistive switching memory device 1000A of FIG. 2A, the gate insulating film 40A surrounds the remaining planes except for the lateral side of the device separation insulating film 60 of the gate electrode 50 in which multiple layers exist in the xy plane direction, and the gate structures of each memory cell may be divided by insulating layer patterns 30I. In other embodiments, the gate insulating film 40B may be provided by a portion of the common gate insulating film extended along the semiconductor channel layer 23. For example, as in the three-dimensional resistive switching memory device 1000B of FIG. 2B, the gate insulating film 40B may be disposed as a shape surrounding the semiconductor pillar 20 extended in the vertical direction of the substrate 10. Then, the semiconductor pillar 20, and the pillars including the gate insulating layer 40B surrounding the semiconductor pillar 20 may be disposed inside a structure formed by alternately stacking the insulating film patterns 30I and the gate electrodes 50 including the conductive film. In each memory cell, the gate insulating film 40B of each memory cell may be in continuous contact to the semiconductor pillar 20 or may be formed of a common material layer, and the gate electrode 50 is separated for each memory cell by the insulating film pattern 30I. Further, in various embodiments, the gate insulating films 40A and 40B may include any one selected from the group consisting of Al₂O₃, SiO₂, HfO₂, ZrO₂, Ta₂O₅, LaO, LaAlO, LaHfO and HfAlO, or a combination thereof.

In one embodiment, the metal element of the metal oxide constituting the semiconductor channel layer 23 may be zinc (Zn), nickel (Ni), niobium (Nb), titanium (Ti), zirconium (Zr), hafnium (Hf), molybdenum (Mo), magnesium (Mg), cobalt (Co), iron (Fe), copper (Cu), aluminum (Al), manganese (Mn), or a combination thereof. The metal oxide may have a polycrystalline amorphous structure, a structure in which nano crystal grains are dispersed, or a structure in which they are mixed. For example, the metal oxide may have an amorphous structure or a structure in which nano crystal grains are dispersed in the amorphous structure. Further, in one embodiment, the semiconductor channel layer 23 may be a single layer of metal oxide, or a composite layer in which different metal oxides are laminated.

In other embodiments, source/drain (S/D) may be present at both ends of each memory cell, and source/drain (S/D) may be present at both ends of the semiconductor channel layer 23 of each memory cell. The source/drain (S/D) may be part of the semiconductor channel layer 23, may include a material different from that of the semiconductor channel layer 23, and may be a portion which is continuously or discontinuously present in the semiconductor channel layer 23. The source/drain (S/D) may exist separately from the semiconductor channel layer 23 while at least a portion of the source/drain (S/D) is in contact with the semiconductor channel layer 23. In addition, the source/drain (S/D) may include a source/drain (S/D) contact portion in at least any part thereof, and the source/drain (S/D) contact portion may be same as the source/drain (S/D) or may contain the materials different from those of the source/drain (S/D). At least a portion of the semiconductor channel layer 23 may contact the contact portion of the source/drain (S/D). In one embodiment, the source/drain (S/D) or source/drain (S/D) contact portion may form a Schottky contact together with the gate insulating films 40A, 40B, and may form a non-Schottky junction together with the semiconductor channel layer 23. In the case of a Schottky junction, since the energy of the moving charges is remarkably different from each other, the moving charges show low mobility and thus, the moving charges moving through the source/drain (S/D) in each memory cell can be prevented from leaking to the electrodes (GE). In other examples, the source/drain (S/D) may have a doping level identical to that of channel region, and then implemented by electrically doping effect due to electrical field of two neighboring gate electrodes.

FIG. 3C is an enlarged cross-sectional view showing a structure of a unit memory cell region of a three-dimensional non-volatile semiconductor memory device 1000C further including a conductivity enhancement layer 24 according to an embodiment of the present invention, and FIG. 3D is an enlarged cross-sectional view showing a structure of an unit memory cell region of the three-dimensional non-volatile semiconductor memory device 1000D further including the conductivity enhancement layer 24 according to the another embodiment of the present invention. The perspective views of the three-dimensional resistive switching memory devices 1000C and 1000D including the conductivity enhancement layer 24 are not illustrated. However, three-dimensional resistive switching memory device 1000C may refer to the perspective view of FIG. 2A, the three-dimensional resistive switching memory device 1000D may refer to the perspective view of FIG. 2B, and there is a difference that it further comprises a conductivity enhancement layer 24.

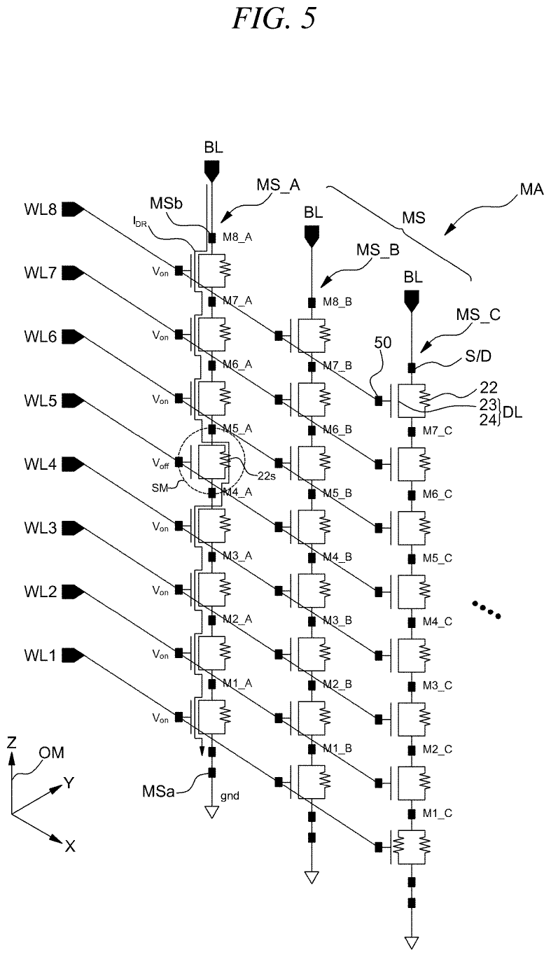

In one embodiment, the three-dimensional resistive switching memory devices 1000C and 1000D may further include a conductivity enhancement layer 24 which is disposed between the semiconductor channel layer 23 and the gate insulating films 40A and 40B, and extended in the vertical direction along the semiconductor channel layer 23. Further, the conductivity enhancement layer 24 may have a conductivity greater than the conductivity of the off-state of the metal oxide of the semiconductor channel layer 23. Each memory cell may have an on-state and an off-state, and a memory cell (SM in FIG. 5) selected from the memory cells may have an off-state, and in the off-state, the current flowing from one end of the selected memory cell SM to the other end thereof flows through the variable resistor layer 22, and among the memory cells, unselected memory cells have an on-state, and in on-state, the current flowing through the unselected memory cell may flow through the semiconductor channel layer 23, the conductivity enhancement layer 24, or a dual channel layer including both of the semiconductor channel layer 23 and the conductivity enhancement layer 24. Since the resistance of the semiconductor channel layer 23, the conductivity enhancement layer 24 of the unselected memory cells, or the dual channel layer DL including both of the semiconductor channel layer 23 and the conductivity enhancement layer 24 of the unselected memory cells is very small as compared to the resistance of the selected memory cell SM, the voltage to be applied by the current is mostly applied to the variable resistance layer of the selected memory cell SM. In order to avoid a duplicate description, a detailed description of the on-state and the off-state will be described later in FIG. 5.

In order to realize a low-power and high-performance semiconductor memory device, it is preferable that each memory cell has high electrical conductivity. Accordingly, when the conductivity enhancement layer 24 capable of reinforcing the conductivity of the semiconductor channel layer 23 is further included in the semiconductor channel layer 23 and the gate insulating films 40A and 40B, it is possible to implement the dual channel layer DL having an electrical conductivity remarkably exceeding an electrical conductivity of the semiconductor channel layer 23. In addition, in order for the semiconductor memory device to have high reliability, it is preferable that most of the current flowing through both ends of the selected memory cell SM under the on-state of the selected memory cell flows through the variable resistance layer 22. As the conductivity of the semiconductor channel layer 23 or the dual channel layer DL is getting higher and the resistance thereof is getting lower, the current in the selected memory cell SM flows the variable resistance layer 22, and therefore, reliability of the semiconductor memory device may be increased. When the conductivity enhancement layer 24 is further included, the conductivity of the dual channel layer DL including the semiconductor channel layer 23 and the conductivity enhancement layer 24 is improved to enhance the amount of current flowing under on-state. Therefore, the on/off ratio of the current of the dual channel layer DL may be increased.

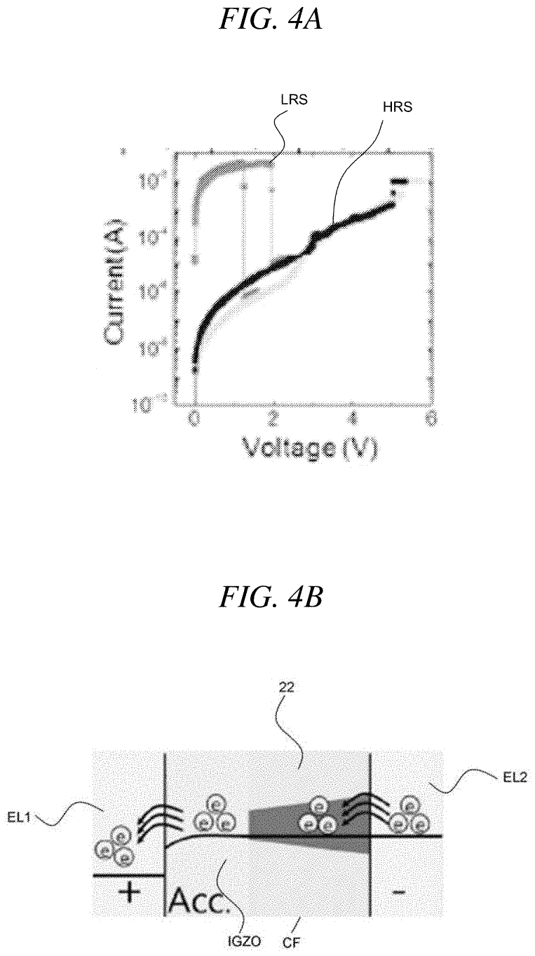

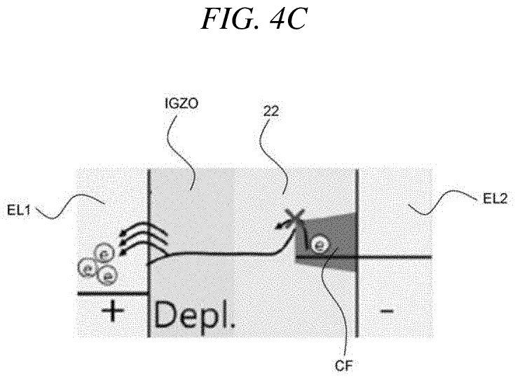

FIG. 4A is an IV measurement graph when indium-gallium-zinc oxide (IGZO) is utilized as an electrode of a variable resistance material according to an embodiment, and FIG. 4B is a schematic diagram showing the movement of the conductive filament (CF) and electrons under a low resistance state (LRS) of the variable resistance material, and FIG. 4C is a schematic diagram showing the movement of the conductive filament (CF) and electrons under a high resistance state (HRS) of the variable resistance material. In one embodiment of the present invention, the variable resistance material is TiO₂, and a platinum (Pt) electrode may be used as a non-limiting example for I-V measurement.

In one embodiment, the metal oxide of the semiconductor channel layer 23 may include indium-gallium-zinc oxide (IGZO), indium-tin oxide (ZTO), or a combination thereof. The conventional semiconductor channel layer is made of poly-Si. However, when the semiconductor channel layer 23 is used as an electrode of the variable resistance layer 22 as in one embodiment of the present invention, the polysilicon may not be suitable. In general, a metal electrode is used as the electrode of the variable resistance material. In addition, when the resistance change mechanism of the variable resistance material includes formation and destruction of filaments due to the movement of oxygen ions and/or oxygen vacancy, polysilicon may not implement a smooth exchange of oxygen with the variable resistance layer 22, and therefore, reversible resistance switching of the variable resistance layer 22 may not be possible. The noble metal elements, such as platinum (Pt), Pd (palladium), Ru (ruthenium), or Ir (iridium), which are commonly used as electrodes of the variable resistance material, show high oxygen permeability. Unlike the fact that the noble metals function as an oxygen reservoir, when polysilicon is used as an electrode, the movement of oxygen ions into or out of the variable resistance material may not be smoothly performed due to the high affinity of the polysilicon with oxygen. In addition, since the noble metal elements show conductivity, they are not suitable as a material for the semiconductor channel layer 23. When the semiconductor channel layer 23 includes the indium-gallium-zinc oxide (IGZO), indium-tin oxide (ZTO), or a combination thereof, and acts as an electrode of the variable resistance layer 22, the indium-gallium-Zinc oxide (IGZO) and indium-tin oxide (ITO) have semiconductor physical properties, so they can be turned on and off by conductive channels, and since they are oxides, oxygen ions into or out of the oxide-based variable resistance material has high mobility, the resistance change characteristic of the variable resistance material may be improved.

Referring to FIG. 4A, when the initial voltage applied to both ends of the indium-gallium-zinc oxide (IGZO) and the variable resistance material in the experimental example of the present invention starts at 0 V, and the voltage of the electrode contacting the indium-gallium-zinc oxide (IGZO) is increased as (+) voltage, it may be changed from a low resistance state to a high resistance state at 1.5 V to 2 V, and it may be changed from a high resistance state to a low resistance state at 4 V to 5 V when the voltage is continuously increased. Referring to FIG. 4B, in a low resistance state, since a conductive filament (CF) is present in the variable resistance material, electron mobility between the indium-gallium-zinc oxide (IGZO) and the variable resistance material is high. Referring to FIG. 4C, it can be seen that in the high resistance state, the conductive filament CF of the variable resistance material is destroyed, and the movement of electrons between the indium-gallium-zinc oxide (IGZO) and the variable resistance material is reduced. The increase and decrease of the electron mobility is due to the formation or destruction of the conductive filament (CF), and the formation or destruction of the conductive filament (CF) is due to oxygen ions moving between the indium-gallium-zinc oxide (IGZO) and the variable resistance material according to the applied voltage. Accordingly, when the semiconductor channel layer 23 includes the indium-gallium-zinc oxide (IGZO), indium-tin oxide (ITO) or a combination thereof instead of poly-silicon, a resistance change due to formation or destruction of the conductive filament CF of the variable resistance layer 22 may be easily performed by virtue of active oxygen ion mobility of the semiconductor channel layer 23 and the variable resistance layer 22.

In other embodiments, since the thickness of the semiconductor channel layer 23 may be in the range of 10 nm to 60 nm Regarding the semiconductor channel layer 23, the conductive channels are formed or destroyed according to a voltage applied to each memory cell by the gate electrode 50, the unselected memory cells shows turn-on-state, and the selected memory cells shows turn-off-state. In an example, when the thickness of the semiconductor channel layer 23 is less than 10 nm, it is difficult to form a conductive channel such that a current having a sufficient size to drive the memory device may flow. In addition, the conductive channel formed in the semiconductor channel layer 23 has a thickness of about 5 nm, and even if the thickness of the semiconductor channel layer 23 increases, the thickness of the conductive channel does not change significantly. When the thickness of the semiconductor channel layer 23 exceeds 60 nm, the size of the voltage to be applied to the gate electrode GE in order to form the conductive channel increases and thus, excessive power consumption is required, and therefore, this demerit can be a hindrance to the implementation of the memory device which can be driven with low power.

In one embodiment, the semiconductor channel layer 23 may have a straight or pipe-shaped bit cost scalable (BICs) structure or a combination structure thereof. The array structure of the three-dimensional resistive switching memory device may be, for example, a channel laminated structure, a straight BICs structure (straight-shaped Bit Cost Scalable structure), and a pipe-shaped BICs (pipe-shaped Bit Cost Scalable structure), and the above structures are only exemplary, and the present invention is not limited thereto.

FIG. 5 is an electrical circuit diagram showing the electrical function of each part of the three-dimensional resistive switching memory devices 1000C and 1000D according to an embodiment of the present invention. The three-dimensional resistive switching memory devices 1000A and 1000B according to another embodiment may include the semiconductor channel layer 23 instead of the dual channel layer DL, and the electrical functions and operation method of each part of the three-dimensional resistive switching memory devices 1000a, 1000B, 1000C, 1000D according to various embodiments the are very similar, and thus, they will be described later together.

Referring to FIG. 5, as described above, the plurality of memory strings MS, for example, may be arranged in a plane or may be laminated in the vertical direction, in a row direction (x-axis direction) and a column direction (y-axis direction) within a space that can be specified by the coordinate system OM. The plurality of memory strings MS may constitute the memory array MA. The X-axis direction and the Y-axis direction may be orthogonal or have any acute angle or obtuse angle, such as 60° or 120°. In addition, the memory strings MS are not limited to a configuration which is linearly arranged side by side along the x-axis or the y-axis, and, instead, may be arranged in any regular meander pattern, and the embodiment of the present invention is not limited thereto. The first end MSa of the memory strings MS is connected to a source line (not shown) and grounded, and the second end MSb is connected to the bit lines BL0, BL1, and BL2, respectively. The gate electrode 50 of each memory cell may be electrically connected to the word lines WL1 to WL8. Each word line WL1 to WL8 may be integrated with the gate electrode 50 of each memory cell, and the present invention is not limited thereto. The gate electrode 50 may have a gate-all-around (GAA) shape surrounding the semiconductor pillar 20 of each memory cell region.

In one embodiment, the semiconductor channel layer 23 and the variable resistance layer 22 may have a type of a resistor connected in parallel, and in another embodiment, when the conductivity enhancement layer 24 is further included, the dual channel layer DL including the semiconductor channel layer 23 and the conductivity enhancement layer 24; and the variable resistance layer 22 may be a resistor connected in parallel. The three-dimensional resistive switching memory device 1000A and 1000B apply a turn-off voltage (V_{off}) to the gate electrode 50 of the selected memory cell SM among a plurality of memory cells; apply turn-on voltage (Vₒₙ) to the gate electrodes 50 of the unselected memory among the plurality of memory cells; change a current signal flowing through the parallel connected semiconductor channel layer 23 and the variable resistance layer 22 among a plurality of memory cells; and change the size of the resistance of the variable resistance layer 22 of the selected memory cell SM to store (or write) an information. In another embodiment, the dual channel layer DL including the semiconductor channel layer 23 and the conductivity enhancement layer 24, and the variable resistance layer 22 may be connected in parallel. In another embodiment, the three-dimensional resistive switching memory devices 1000C and 1000D apply a turn-off voltage (V_{off}) to the gate electrode 50 of the selected memory cell SM among the plurality of memory cells, and apply a turn-on voltage (Vₒₙ) to gate electrodes 50 of unselected memory cells among the plurality of memory cells. Thus, in the unselected memory cells to which the turn-off voltage (V_{off}) is applied, the current flows through the dual channel layer DL, and in the selected memory cell SM to which the turn-off voltage (V_{off}) is applied, the electric charges of the conductivity enhancement layer 24 move to the semiconductor channel layer 23. Therefore, the current signal flowing in the parallel connected dual channel layer DL and the variable resistance layer 22 is changed by increasing the resistance of the dual channel layer DL, and an information may be stored by changing the magnitude of the resistance of the variable resistance layer 22 of the selected memory cell SM. For example, in the case of the selected memory cell SM, since the resistance of the semiconductor channel layer 23 or the dual channel layer DL is greater than the resistance of the variable resistance layer 22, the driving current (IDR) flows through the variable resistance layer 22 (22s in FIG. 5, in an off-state), and in the case of the unselected memory cells, the resistance of the semiconductor channel layer 23 or the dual channel layer DL is smaller than the resistance of the variable resistance layer 22. Thus, the driving current (IDR) may flow through the semiconductor channel layer 23 or the dual channel layer DL (on-state). In addition, since the resistance of the variable resistance layer 22 of the selected memory cell SM is greater than the sum of the resistances of the semiconductor channel layer 23 or the dual channel layer DL of the unselected memory cells, most of the driving current (IDR) of the memory string MS including the selected memory cell SM flow through the variable resistance layer 22. Accordingly, the size of the resistance of the variable resistance layer 22 of the selected memory cell SM may be changed according to the magnitude of the driving current IDR or the size of the driving signal applied to the bit line. In addition, since the conductivity of the conductivity enhancement layer 24 may have a value that is 10 times greater than the conductivity of the variable resistance layer 22, most of the current in unselected memory cells flows through a dual channel layer DL including the conductivity enhancement layer 24. For example, indium-tin oxide (ITO) may have a conductivity of about 10 times greater than that of indium-gallium-zinc oxide (IGZO), thereby enhancing conductivity of the semiconductor channel layer 23. On the other hand, in the off-state of the selected memory cell SM, a part of the charge of the conductivity enhancement layer 24 moves to the semiconductor channel layer 23 by the turn-on voltage, so that the conductivity of the conductivity enhancement layer 24 may be lower than that of the on-state. For example, when the semiconductor channel layer 23 and the conductivity enhancement layer 24 are n-type materials, when a negative voltage is applied to the gate electrode 50 of the selected memory cell SM, the electrons present in the conductivity enhancement layer 24 are introduced into the semiconductor channel layer 23 due to an electric field or electric force generated by the negative voltage, thereby reducing the conductivity of the conductivity enhancement layer 24, and consequently, a resistance of the double channel layer DL may increase. Likewise, when the semiconductor channel layer 23 and the conductivity enhancement layer 24 are p-type materials, and if a positive voltage is applied to the gate electrode 50, it is possible to operate in the same manner as described above.

Referring back to FIGS. 3C and 3D, the conductivity enhancement layer 24 may have the same conductivity type as the metal oxide of the semiconductor channel layer 23. For example, when the semiconductor channel layer 23 is a p-type semiconductor having holes as a charge carrier, the conductivity enhancement layer 24 may be a p-type conductive oxide film. Conversely, when the semiconductor channel layer 23 is an n-type semiconductor having electrons as a charge carrier, the conductivity enhancement layer 24 may be an n-type conductive oxide film. In various kinds of embodiments, the p-type conductive oxide layer may include perovskite materials such as SrTiO₃, LaTiO₃, LaCoO₃, SrCoO₃, SrRuO₃, SrMgO₃, LaNiO₃, compounds such as ZnCo₂O₄, ZnRh₂O₄, ZnIr₂O₄, or combinations thereof. In addition, in one embodiment, the materials or compounds may be annealed in an oxygen atmosphere to obtain a conductivity enhancement layer 24 having a higher conductivity. In another embodiment, when the semiconductor channel layer 23 is an n-type semiconductor, for example, indium-gallium-zinc oxide (IGZO), indium-tin oxide (ZTO), the conductivity enhancement layer 24 may include at least any one of the transparent conductive materials such as indium-tin oxide (ITO) and indium-zinc oxide (InZnO) or the opaque conductive materials such as RuO₂, IrO₂, Co₃O₄, Fe₃O₄.

In other embodiments, the thickness of the conductive enhancement layer 24 may be in the range of 3 nm to 7 nm. The conductivity enhancement layer 24 has conductivity, and when the conductivity enhancement layer 24 exceeds 7 nm, even if a turn-on voltage is applied to implement an off-state in the selected memory cell, the driving current (IDR in FIG. 5) flows through the dual channel layer DL due to conductivity. Thus, the driving current (IDR) may not flow through the variable resistance layer 22 of the selected memory cell SM. In addition, when the thickness is less than 3 nm, since the conductivity of the dual channel layer DL is not sufficiently high in the on-state, in the unselected memory cells the driving current (IDR)) flows through the variable resistance layer 22. Therefore, the on-state is s not clearly distinguished from the off-state, and an operation error may occur. Therefore, it is important to select a conductive reinforcement layer 24 having appropriate thickness, and the thickness may be set to the optimum condition in consideration of these factors such as the operating environment, the thickness of the semiconductor channel layer 23 and the variable resistance layer 22, or the material of the conductive reinforcement layer 24.

Referring again to FIGS. 2A and 2B, the three-dimensional resistive switching memory devices 1000A and 1000B may contact with the one side of the semiconductor channel layer 23 and include a variable resistance layer 22 extended in a vertical direction. In one embodiment, the variable resistance layer 22 may include a unipolar switching material or bipolar switching material. In another embodiment, the variable resistance layer 22 may include phase change materials, and the phase change materials may include chalcogenide compounds. In another embodiment, the variable resistance layer 22 may include a programmable metallization cell (PMC). The programmable metallization cell may include phase change materials in which the ions inside the solid electrolyte are physically rearranged. In various embodiments, the programmable metallization cell may include a relatively stable solid electrolyte such as tungsten (W); and the solid electrolytes having relatively high reactivity such as silver (Ag) or copper (Cu). When the programmable metallization cell is heated, the mobility of ions in the solid electrolyte is improved, thereby reducing the programming threshold voltage. Accordingly, when the variable resistance layer 22 includes the programmable metallization cell, it may have various threshold voltage characteristics according to a temperature range.

In another embodiment, the variable resistance layer 22 may include aluminum oxide (AlOₓ), zirconium oxide (ZrOₓ), titanium oxide (TiOₓ), niobium oxide (NbOₓ), nickel oxide (NiOₓ), zinc oxide (ZnOₓ), manganese oxide (MnOₓ), tungsten oxide (WOₓ), tantalum (Ta) oxide or hafnium (Hf) oxide, and may be, for example, TiO₂. In connection with the variable resistance materials such as TiO₂ or the former oxides, as described above with reference to FIGS. 4A to 4C, oxygen vacancy filaments are formed or destroyed inside the variable resistance layer according to an electric field, and thus a level of a resistance of the variable resistance layer may be adjusted.

Referring back to FIG. 4A to FIG. 5, the three-dimensional resistive switching memory devices 1000C and 1000D may comprise the memory strings MS each of which includes a plurality of memory cells connected in series; the word lines connected to the gate electrode 50 of each of the plurality of memory cells; the bit lines connected to one end of each of the memory strings MS; the source lines connected to the other end of each of the memory strings MS; a row decoder electrically connected to the plurality of memory cells through the word lines; and a column decoder electrically connected to the plurality of memory cells through the bit lines. The plurality of memory cells are spaced apart in a first direction and a second direction different from the first direction on the substrate. Each memory cell may further comprises a semiconductor channel layer 23 including metal oxides extended in a vertical direction on the substrate; the variable resistance layer 22 which is in contact with one side of the semiconductor channel layer 23 and extends in the vertical direction; and a plurality of gate structures having a gate electrode 50 disposed on the other side opposite to the one side of the semiconductor channel layer 23 and defining a plurality of memory cells serially connected to each other along the vertical direction, and a gate insulating films 40A and 40B between the gate electrode 50 and the semiconductor channel layer 23; and a conductivity enhancement layer 24 disposed between the semiconductor channel layer 23 and the gate insulating films 40A and 40B, and extended in the vertical direction along the semiconductor channel layer 23. Furthermore, the conductivity enhancement layer 24 may have a larger conductivity than the off-state conductivity of the metal oxide of the semiconductor channel layer 23. The detailed description of this may refer to the above-mentioned explanation described with referring to FIG. 2A to FIG. 5, unless there are no discrepancies.

In another embodiment, the driving method of the three-dimensional resistive switching memory devices 1000A, 1000B, 1000C, and 1000D may comprise a step for applying a turn-off voltage (V_{off}) to the selected word line, and applying a turn-on voltage (Vₒₙ) to the unselected word line; and a step for applying a driving signal suitable for a programming, erasing, or reading operations to the selected bit line to enable a driving current to flow through a variable resistance layer of a selected memory cell for performing a programming, erasing, or reading operations. As for a detailed description of the electrical functions of the turn-off voltage (V_{off}) and the turn-on voltage (Vₒₙ), references may be made to the above-mentioned disclosure in FIG. 5 if there are no inconsistencies. In one embodiment, the turn-off voltage (V_{off}) may be greater or less than the turn-on voltage (Vₒₙ) depending on the type of material included in the conductivity enhancement layer CL and the semiconductor channel layer 23. For example, in the case of indium-gallium-zinc oxide (IGZO) in the semiconductor channel layer 23, the turn-off voltage (V_{off}) may be 4 V to 5 V, and the turn-on voltage (Vₒₙ) may be 1.5. V to 2 V.

In another embodiment, when the semiconductor channel layer 23 and the conductivity enhancement layer 24 include an n-type material, the turn-off voltage (V_{off}) may be a negative voltage of a magnitude greater than that of the turn-on voltage (Vₒₙ). Therefore, when the turn-off voltage (V_{off}) is applied to the gate electrode 50, some of the electrons of the conductivity enhancement layer 24 move to the semiconductor channel layer 23 and the selected memory cell to which the turn-off voltage (V_{off}) is applied may be switched to an off-state. Similarly, when the semiconductor channel layer 23 and the conductivity enhancement layer 24 include a p-type material, the turn-off voltage (V_{off}) may have a larger positive value than the turn-on voltage (Vₒₙ). Accordingly, when the turn-off voltage (V_{off}) is applied to the gate electrode 50, some of the holes of the conductivity enhancement layer 24 move to the semiconductor channel layer 23, and the selected memory cell to which turn-off voltage (V_{off}) is applied may be switched to an off-state.

The programming step may include a set operation to change the resistance state of the variable resistance layer 22 from a high resistance state (HRS) to a low resistance state LRS), or a reset operation a from a low resistance state to a high resistance state. It may include a reset operation to change to a resistance state. Depending on the resistance state of the variable resistance layer 22, two logics such as “1” or “0” may be implemented. The signal for causing the set operation or the reset operation may be a voltage signal or a current signal, and the signal may be continuous or it may be provided as a type of pulse. The set voltage or the reset voltage depends on the variable resistance layer 22. For example, if the variable resistance layer 22 is bipolar, and the set voltage is positive (+) voltage, the reset voltage is negative (−) voltage, or vice versa. If the variable resistor layer 22 is unipolar, both of the set voltage and the reset voltage may have a positive voltage or a negative voltage. However, this is only an example, and is not limited to a specific voltage. In various embodiments, two or more bit logics other than one bit logic of “1” and “0” may be implemented according to the resistance state of the variable resistance material layer 22.

The read operation may be an operation for determining whether a logic of the variable resistance layer 22 of the selected memory cell SM is “1” or “0”. The voltage applied to the word lines may be applied to each of the memory cells through the gate electrode 50 of each memory cell, and the selected memory cell SM may have an off-state and unselected memory cells may have an on-state. The driving current (IDR) flowing through the memory string MS including the selected memory cell SM is applied to the selected memory cell SM, and the magnitude of the current may vary according to the resistance state of the variable resistance layer 22. Further, the logic of “1” or “0” may be distinguished by the magnitude of the current. In another embodiment, a driving method and a driving circuit may be simplified because the voltages applied to the gate electrode 50 of the selected memory cell SM or the non-selected memory cells selected for the programming, erasing, or reading operations are identical to each other. Accordingly, it is possible to quickly and accurately drive the memory element.

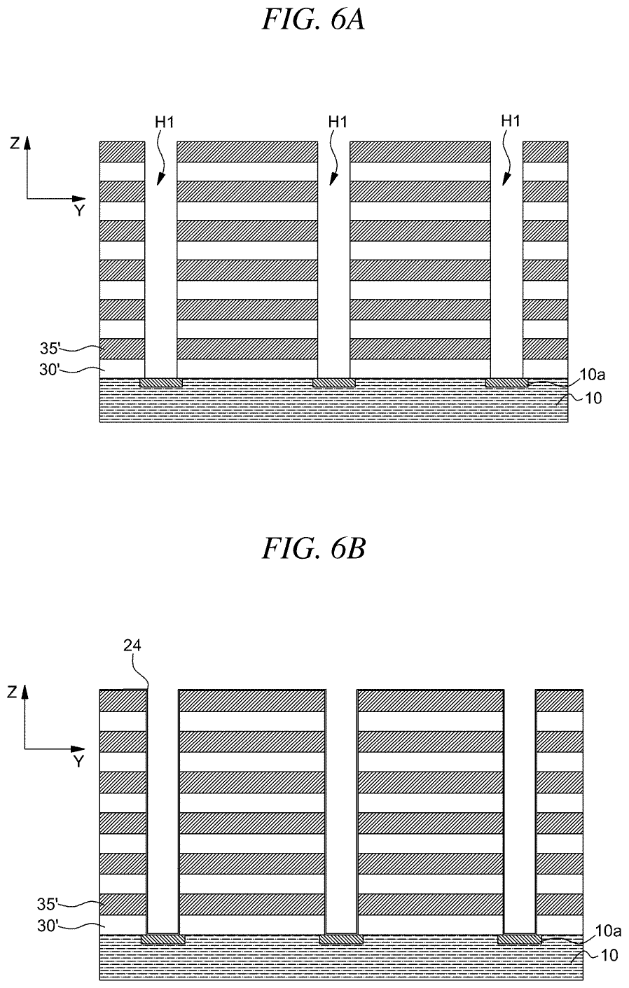

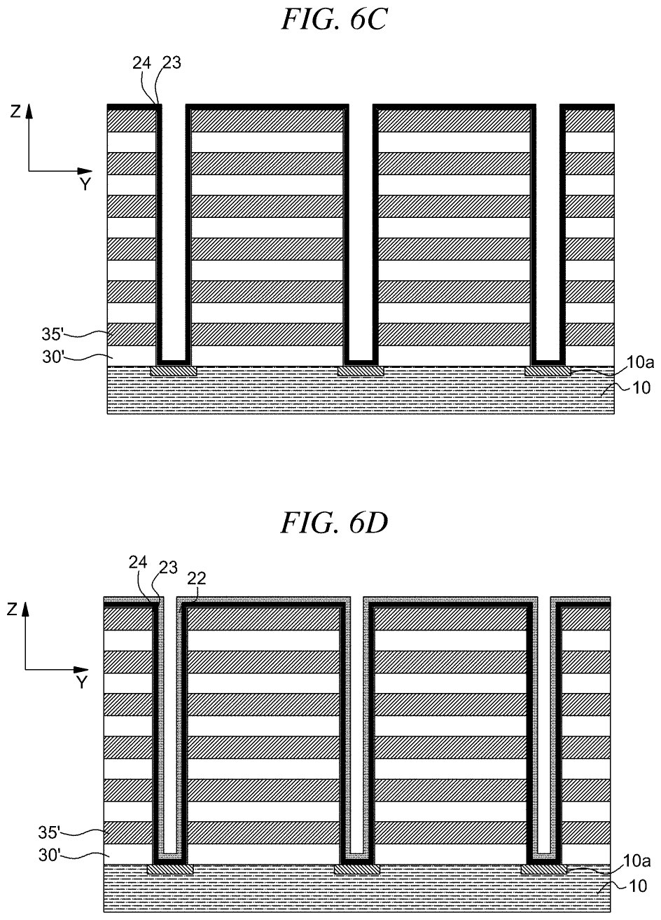

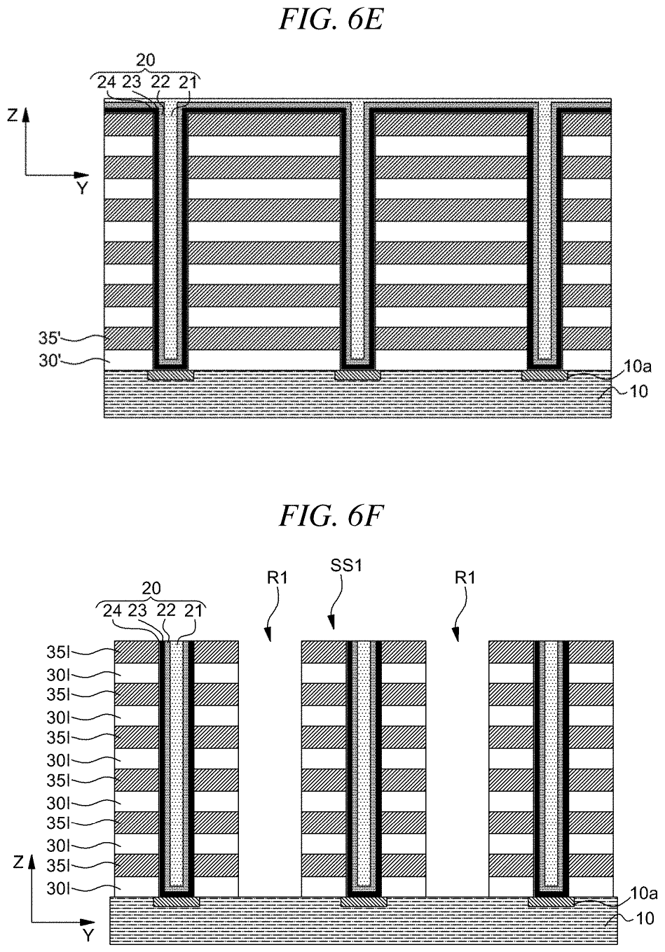

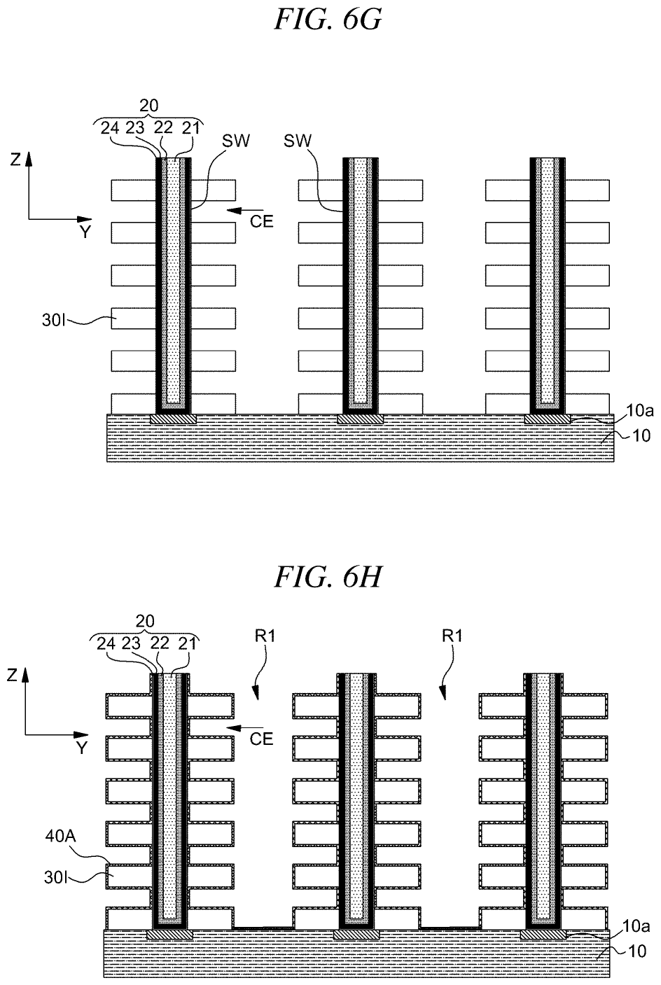

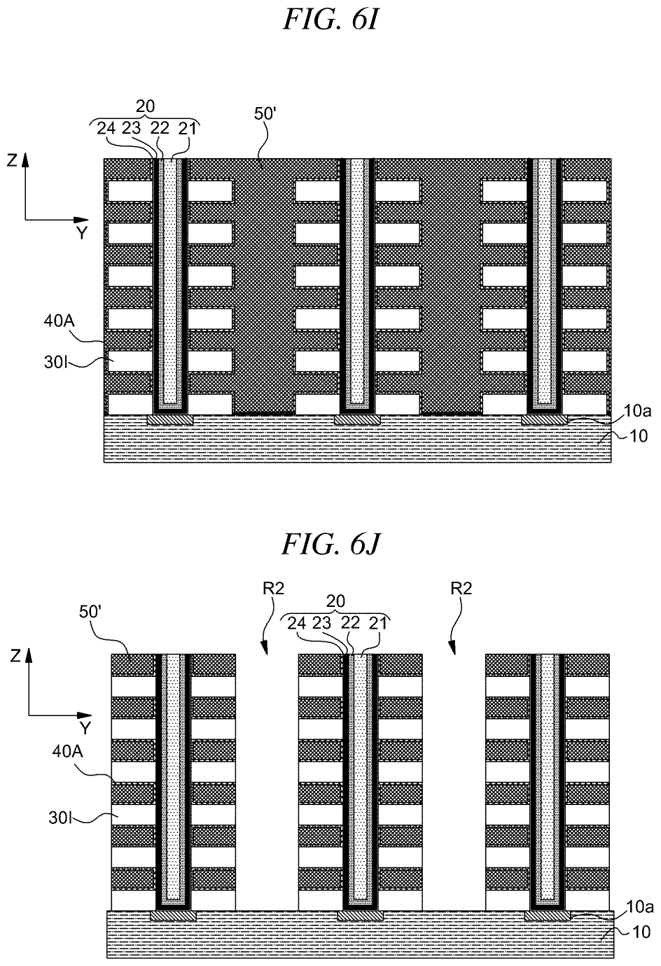

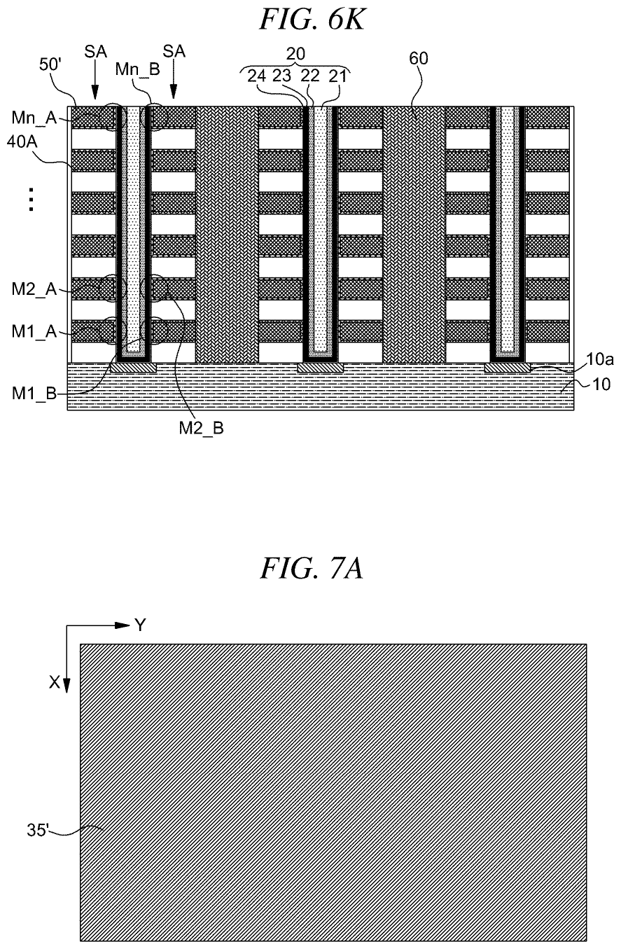

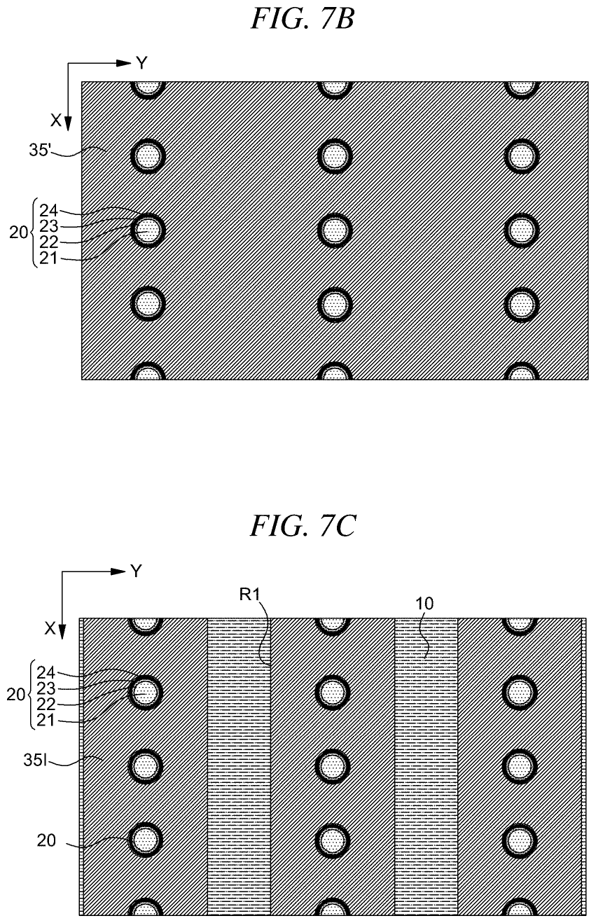

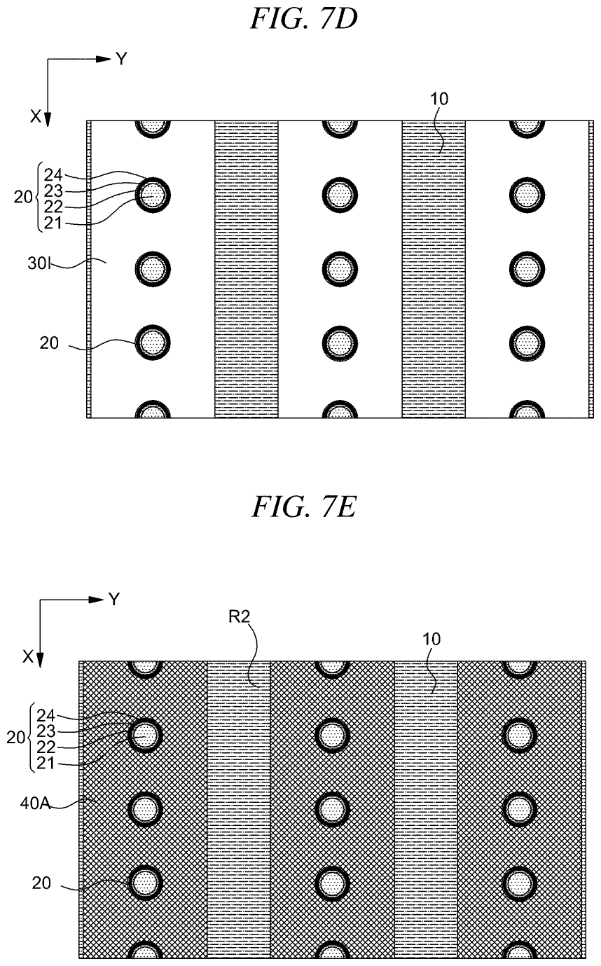

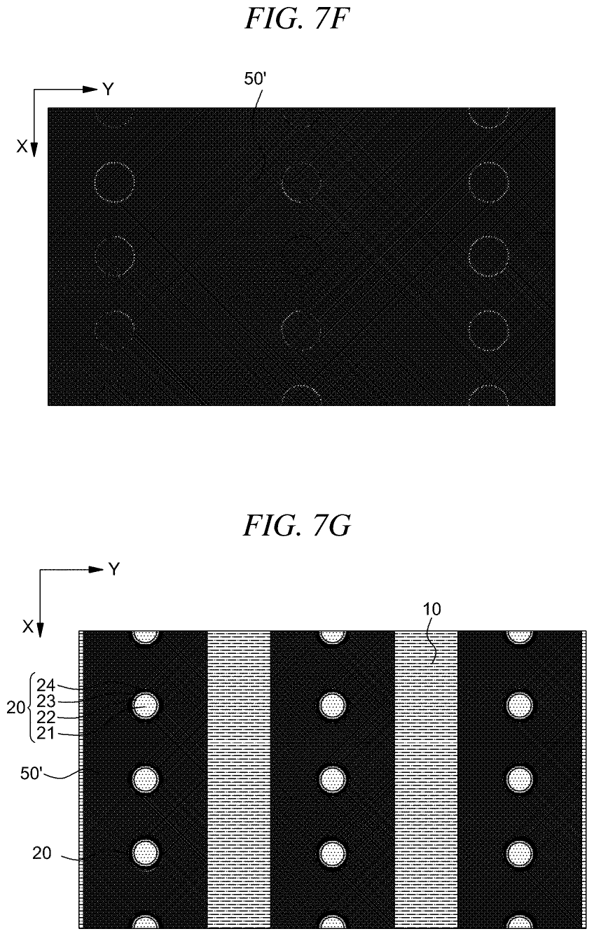

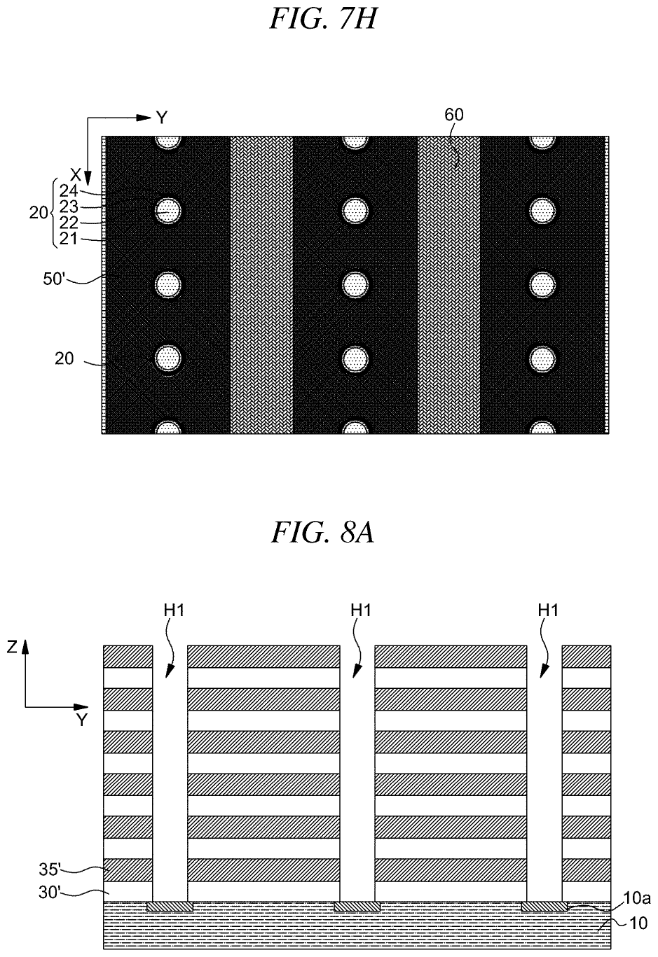

FIG. 6A to FIG. 6K are cross-sectional views sequentially illustrating a method of fabricating a three-dimensional resistive switching memory device 1000C according to an embodiment of the present invention, and FIG. 7A to FIG. 7H is a plane view sequentially showing the fabricating method.

Referring to FIG. 6A and FIG. 7A, a substrate 10 is provided. A conductive member 10a such as an impurity region for forming a source line or wiring may be formed on the substrate 10. The conductive member 10a may be one end of a switching device, a contact, or a connecting member for obtaining a string structure such as a Piped-Bics structure. For example, the conductive member 10a may be one end of the transistor. On the substrate 10, an insulating film 30′ and a sacrificial film 35′ may be alternately laminated, and as shown in FIG. 6A, the first holes H1 which are spaced in the first direction parallel to the substrate 10 and a second different from the first direction, and penetrates the repeatedly laminated insulating film 30′ and sacrificial film 35′ may be formed. The number of repetitive stacks may be determined by considering the number of memory cells, selection transistors, and ground transistors. In one example, the sacrificial film 35′ may be formed from the material which have etch selectivity against the insulating film 30′. For example, when the insulating film 30′ is formed from silicon oxide, the sacrificial film 35′ may be formed from silicon nitride. In addition, the thickness of the insulating film 30′ or the sacrificial film 35′ may be determined by considering a distance between the memory cells, the width of a gate electrode, and etc.

Referring to FIG. 6B, after forming the first holes H1, a step of forming a conductivity enhancement layer 24 may be further included. The conductivity enhancement layer 24 may have the same conductivity type as the metal oxide of a semiconductor channel layer 23. Further, in other embodiments, the conductivity enhancement layer 24 may include indium-tin oxide (ITO).

Referring to FIG. 6C and FIG. 6D, a semiconductor channel layer 23 including metal oxide may be formed on the inner sidewall of the conductivity enhancement layer 24, and a variable resistance layer 22 may be formed on the inner sidewall of the semiconductor channel layer 23. The semiconductor channel layer 23 or the variable resistance layer 22 may be formed by stacking unit thin film layers in a way of layer by layer by an atomic layer deposition process. The semiconductor channel layer 23 and the variable resistance layer 22 may have at least one of covalent bonds and ionic bonds between oxygen atoms and metal elements for constituting the metal oxide. The semiconductor channel layer 23 may be formed by using In₂Ga₂ZnO₇ as a precursor as an unlimited example.

In another embodiment, the method of fabricating the three-dimensional resistive switching memory device may further include a step for annealing the semiconductor channel layer 23, the variable resistance layer 22 and the conductivity enhancement layer 24, wherein the step of annealing may be performed at a temperature ranging from 300° C. to 400° C. By the step of annealing, the contact surfaces of the semiconductor channel layer 23, the variable resistance layer 22, and the conductivity enhancement layer 24 are made uniform, thereby improving contactability and removing the defects that may be formed at the interface of each layer. The annealing process may be preferably performed at about 350° C., and when the temperature of the annealing process is performed below 300° C., the effects such as improving the contact properties of the interface and removing defects may not be sufficiently exhibited. When the temperature of the annealing process is greater than or equal to 400° C., unexpected changes in physical properties such as a phase change of the material of each layer may occur.

Referring to FIG. 6E and FIG. 7B, a semiconductor pillars 20 may be formed by filling a core insulator 21 in the hole formed by the variable resistance layer 22. The step for filling the core insulator 21 may be optionally performed. In one embodiment, the bottom of the semiconductor channel layer 23 may be formed to contact the substrate 10, and the semiconductor channel layer 23 may be electrically connected to a source line formed on the substrate 10.

Referring to FIG. 6F and FIG. 7C, in order to separate from each other the semiconductor pillars 20 aligned in the second direction (y direction) parallel to the substrate 10 and different from the first direction (x direction), a first trench region R1 which is extended in the first direction (x direction) and the vertical direction (z direction) may be formed by patterning the repeatedly laminated insulating film 30′ and the sacrificial film 35′. Therefore, a laminated structure SS1 consisting of an insulating film pattern 30I a sacrificial film pattern 35I, through which the semiconductor pillars 20 pass, may be formed. The first trench region R1 may separate the semiconductor pillars 20 aligned in the second direction (y direction), whereby a laminated structure SS1 consisting of the insulating film pattern 30I and the sacrificial film pattern 35I may be formed.

Referring to FIG. 6G and FIG. 7D, the sacrificial film pattern 35I may be removed from the laminated structure SS1 consisting of the insulating film pattern 30I and the sacrificial film pattern 35I, exposed through the first trench region R1. At this time, only the sacrificial film pattern 35I may be selectively removed by a wet etching process using an etching selectivity ratio of the sacrificial film pattern 35I and the insulating film pattern 30I. As a result, a cell space CE in which sidewalls SW of the semiconductor pillars 20 are exposed between the laminated insulating film patterns 30I may be formed.

Referring to FIG. 6H and FIG. 7E, a gate insulating film 40A may be formed on the substrate 10 on which cell spaces CE are formed. The gate insulating film 40A may be formed through a thin film forming process having excellent step coverage, for example, a chemical vapor deposition process or atomic film deposition process.

Referring to FIG. 6I to FIG. 6K and FIG. 7F to FIG. 7H, a conductive layer 50′ filling at least a portion of the cell spaces CE in which the gate insulating layer 40A is formed may be formed. For example, the conductive layer 50′ may fill all portions of the empty space or only a portion of the cell spaces CE. In another embodiment, the conductive film 50′ fills a portion of the cell spaces CE and may also be etched to enter the inner side of the insulating film 30′ through a wet process. The dotted lines in FIG. 7F indicate the semiconductor pillars 20 arranged under the conductive film 50′. The conductive film 50′ may include a single layer of a conductive film such as titanium nitride film (TiN), tungsten, aluminum, or polysilicon, or two or more laminated structures such as titanium nitride film (TiN)/tungsten (W). Optionally, the second trench region R2 extended in the first direction (x direction) and the vertical direction (z direction) may be formed with respect to the substrate 10 on which the conductive film 50′ is formed. Thereafter, referring to FIG. 6K, an electrical separation between devices in the second direction (y direction) may be achieved by the device isolation insulating layer 60 filling the second trench region R2.

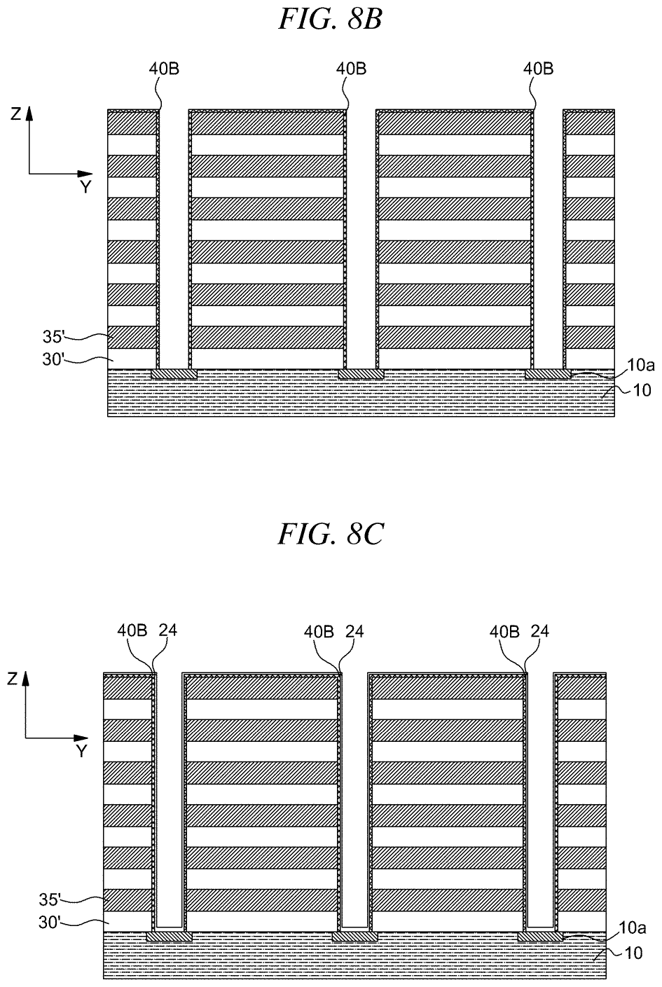

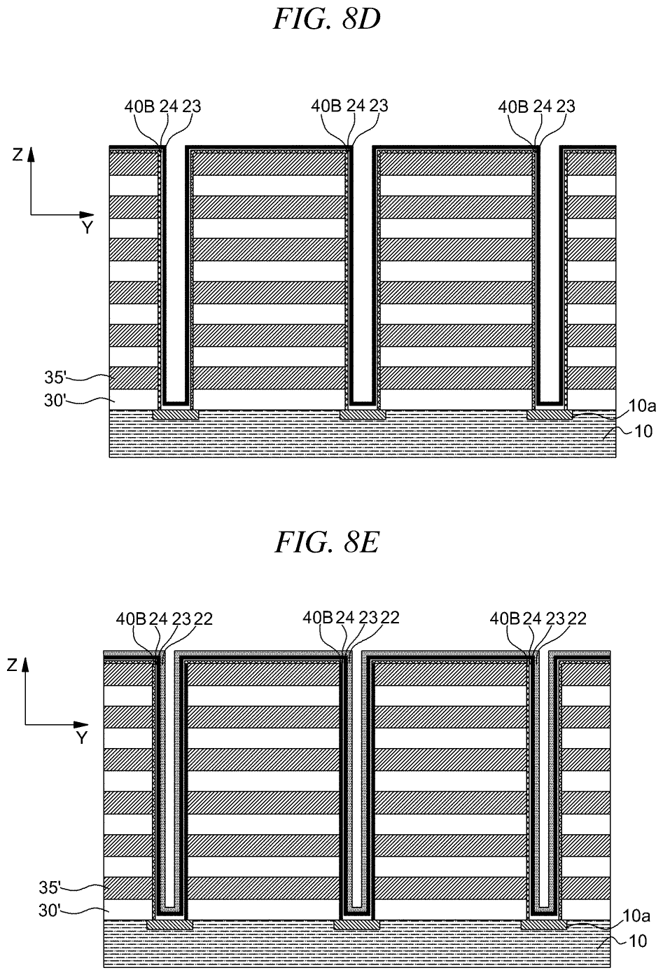

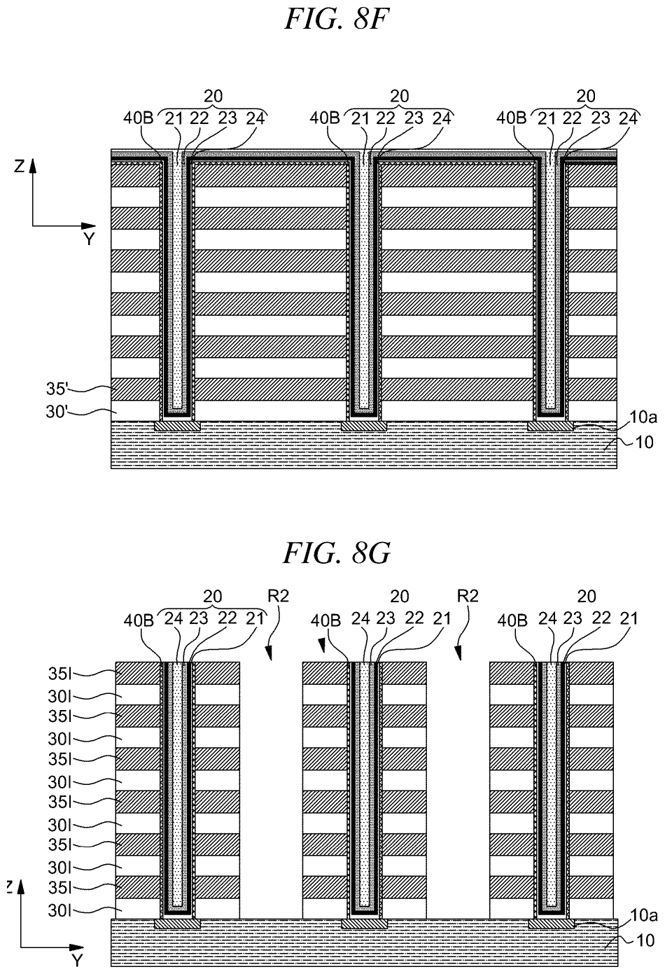

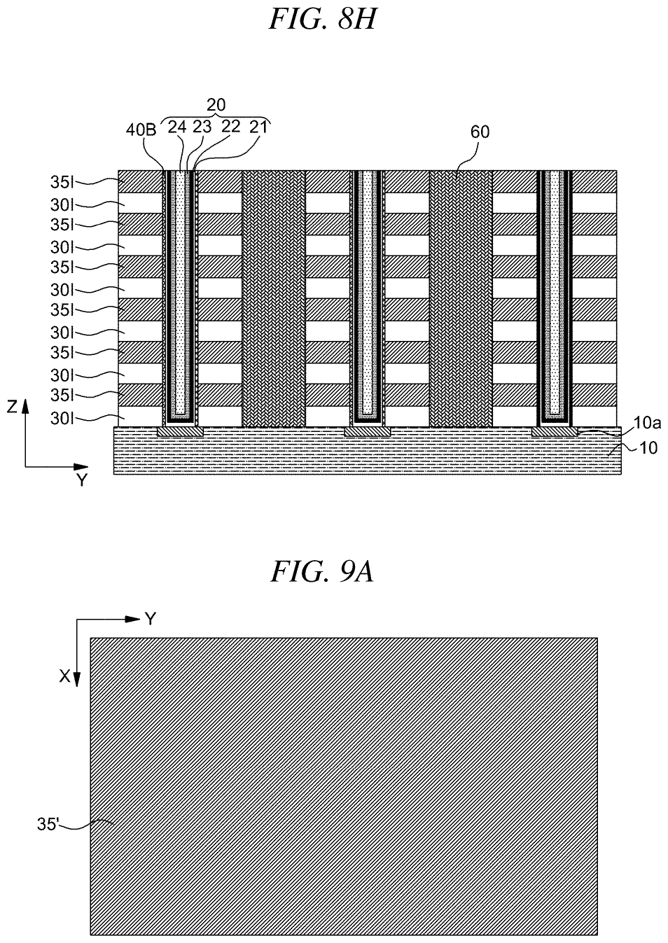

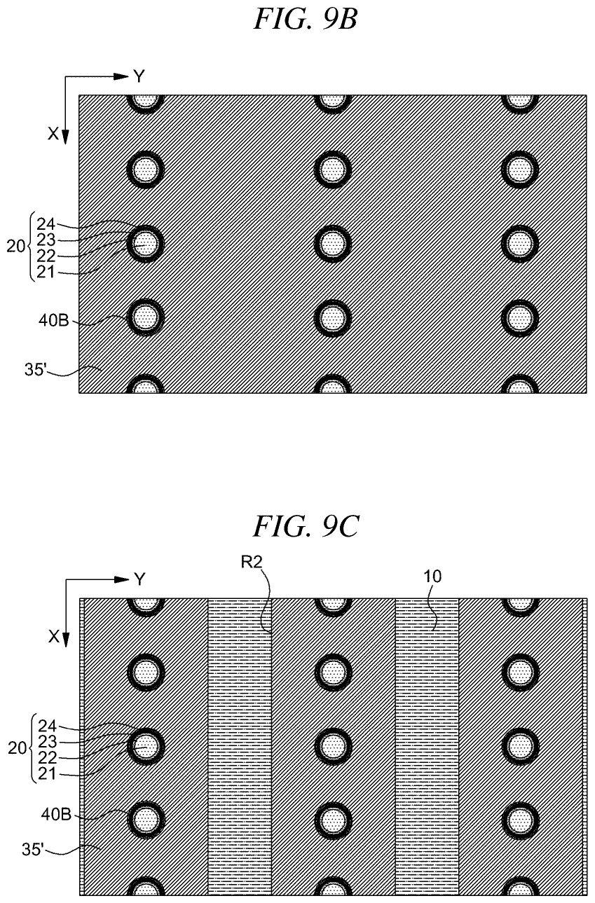

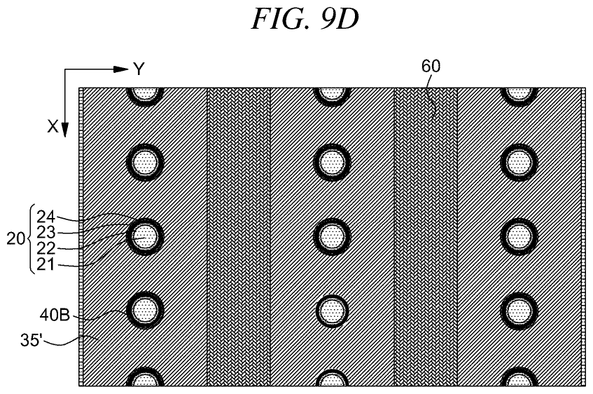

FIG. 8A to FIG. 8H are cross-sectional views sequentially illustrating a method of fabricating a three-dimensional resistive switching memory device 1000D according to an embodiment of the present invention, and FIG. 9A to FIG. 9D are plan views sequentially showing the fabricating method. As for the configuring members of these figures, references may be made to the disclosure regarding configuring members having the same reference numerals as described above with reference to FIG. 6A to FIG. 6K and FIG. 7A to FIG. 7G.

Referring to FIG. 8A and FIG. 9A, a substrate 10 may be provided. A conductive member 10a such as an impurity region or wiring may be formed on the substrate 10. This is exemplary, and the conductive member 10a may be one end of a switching device, a contact, or a connecting member for obtaining a string structure such as a Piped-Bics structure. On the substrate 10, the insulating film 30′ and the conductive film 35′ may be alternately laminated. The number of repetitive stacks may be determined by considering the number of memory cells, the selection transistors, and the ground transistors. In one embodiment, the conductive film 35′ may include a conductive metal or a conductive metal oxide or nitride. Thereafter, holes H1 penetrating the stack of the insulating film 30 ‘ and the conductive film 35’ repeatedly laminated in the vertical direction may be formed. The conductive film 35′ may have polysilicon of a high-concentration impurity, aluminum, tungsten, titanium nitride film (TiN), or a laminated structure having two or more layers. This is only exemplary and the present invention is not limited thereto.

Referring to FIG. 8B to FIG. 8D, a gate insulating film 40B may be formed on inner sidewalls of holes H1 penetrating the repeatedly laminated insulating film 30′ and the conductive film 35′. After the gate insulating film 40B is formed, a semiconductor channel layer 23 including a metal oxide may be formed on the inner sidewall of the gate insulating film, and the metal oxide may have at least any one of the covalent bond and the ion bond between the metal element and the oxygen atom constituting the metal oxide. In another embodiment, the conductivity enhancement layer 24 may be formed after the gate insulating layer 40B is formed, and the semiconductor channel layer 23 may be formed after the conductivity enhancement layer 24 is formed. In addition, a step for etching a portion of the gate insulating layer 40B may be further performed, so that the bottom of the semiconductor channel layer 23 or the conductivity enhancement layer 24 may be at least partially contacted with the substrate 10. The etching may be performed by a dry etching process such as plasma etching.

Referring to FIG. 8E, after forming the semiconductor channel layer 23, the variable resistance layer 22 may be formed on the inner sidewall of the semiconductor channel layer 23. The gate insulating film 40B, the semiconductor channel layer 23 and the variable resistance layer 22 may be formed through a thin film forming process having excellent step coverage, for example, a chemical vapor deposition process or an atomic layer deposition process. In another embodiment, the method of fabricating the three-dimensional resistive switching memory device further may perform a step for annealing the semiconductor channel layer 23, the variable resistance layer 22 and the conductivity enhancement layer 24, wherein the step of annealing may be performed at a temperature ranging from 300° C. to 400° C. As for a detailed description of the operating temperature of the annealing step, a reference may be made to the foregoing disclosure.

Referring to FIG. 8F and FIG. 9B, the core insulator 21 may be optionally filled on the variable resistance layer 22 to fill the space of the inner wall of the variable resistance layer 22. Due to such a filling process, a semiconductor pillar 20 including a core insulator 21, a variable resistance layer 22, a semiconductor channel layer 23 and a conductivity enhancement layer 24 may be provided. The bottom of the semiconductor pillar 20 may be formed to contact the substrate 10, and the semiconductor pillar 20 may be electrically connected to a source line formed on the substrate 10.

Referring to FIGS. 8G, 8H, 9C, and 9D, a second trench region R2 which is extended in the first direction (x direction) and a vertical direction (z direction) in the laminated structure of the insulating film 30′ and the conductive film 35′ with respect to the substrate 10 on which the semiconductor pillar 20 is formed, and which is spaced apart in a second direction (y direction), may be formed. A laminated structure SS1 of the insulating film pattern 30I and the conductive film pattern 35I separated from each other by the second trench region R2 may be formed. Optionally, the insulating layer 60 may be formed by filling the insulator in the second trench region R2. The electrical separation between the memory strings MS adjacent in the second direction (y direction) may be achieved by the device isolation insulating layer 60.

As described above, when a bit line voltage is applied to the source-drain electrode S/D, a current flows through each memory string MS. A turn-off voltage is applied to the selected word line, and in the case of the selected word line, the resistance of the semiconductor channel layer 23 is increased in order to allow the current flowing through each of the memory strings MS to flow through the variable resistance layer 22. For example, when the semiconductor channel layer 23 is indium-gallium-zinc oxide (IGZO), the turn-off voltage may be from 4 V to 5 V, and is applied to the gate electrode 50 of the selected word line. Conversely, in the case of unselected memory cells, the resistance of the semiconductor channel layer 23 may be reduced by applying a turn-on voltage, so that the current flowing through each of the memory strings MS may flow into the semiconductor channel layer 23. For example, when the semiconductor channel layer 23 is indium-gallium zinc oxide (IGZO), the turn-on voltage may be from 1.5 V to 2 V, and is applied to the control gate electrodes 50 of the unselected word lines. The turn-off voltage and the turn-on voltage may vary depending on the factors such as a type, a thickness, and a concentration of a doping material of the semiconductor channel layer 23 and the variable resistance layer 22, a doping material, and a of the doping material. In another embodiment, when the semiconductor channel layer 23 includes materials which exhibit a nonlinear change of a resistance magnitude according to a change of the applied voltage, for example, the magnitude of the turn-off voltage in the case of NbO₂ or VO₂ may be smaller than the magnitude of the turn-on voltage. Alternatively, when the resistance of the semiconductor channel layer 23 made of the indium-gallium zinc oxide (IGZO) is increased, the driving current IDR flowing through each of the memory strings MS flows through a variable resistance layer 22 in the selected memory cell SM, and in non-selected memory cells, the driving current IDR may flow through the semiconductor channel layer 23 due to the decrease in the resistance of the semiconductor channel layer 23.

The resistive switching memory device and/or a memory controller according to the present invention may be mounted by using various types of packages. For example, a flash memory device and/or a memory controller according to the present invention may be mounted by using PoP (Package on Package), Ball grid arrays (BGAs), Chip scale packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Thin Quad Flatpack (TQFP), Small Outline (SOIC), Shrink Small Outline Package (SSOP), Thin Small Outline (TSOP), System In Package (SIP), Multi Chip Package (MCP), Wafer-level Fabricated Package (WFP), or Wafer-Level Processed Stack Package (WSP).

What is claimed is:

1. A three-dimensional resistive switching memory device including a plurality of memory cells, wherein each memory cell comprises,
a semiconductor channel layer comprising a metal oxide extended in a vertical direction on the substrate;
a variable resistance layer contacting one side of the semiconductor channel layer and extended in the vertical direction; and
a plurality of gate structures having a gate electrode disposed on the other side opposite to the one side of the semiconductor channel layer and defining the plurality of memory cells serially connected to each other along the vertical direction, and a gate insulating film arranged between the gate electrode and the semiconductor channel layer.

2. The three-dimensional resistive switching memory device of the claim 1, wherein the gate insulating film is provided separately for each gate electrode along the semiconductor channel layer.

3. The three-dimensional resistive switching memory device of the claim 1, wherein the gate insulating film is provided by a portion of a common gate insulating film extended along the semiconductor channel layer.

4. The three-dimensional resistive switching memory device of the claim 1, wherein the metal oxide comprises indium-gallium-zinc oxide (IGZO), indium-tin oxide (ITO), or a combination thereof.

5. The three-dimensional resistive switching memory device of the claim 1, further comprising a conductivity enhancement layer disposed between the semiconductor channel layer and the gate insulating layer, and extended in the vertical direction along the semiconductor channel layer,
wherein the conductivity enhancement layer has a conductivity greater than that of off-state of the metal oxide of the semiconductor channel layer.

6. The three-dimensional resistive switching memory device of the claim 5, wherein the conductivity enhancement layer has the same conductivity type as that of the metal oxide of the semiconductor channel layer.

7. The three-dimensional resistive switching memory device of the claim 5, wherein the conductivity enhancement layer comprises indium-tin oxide (ITO).

8. The three-dimensional resistive switching memory device of the claim 5, wherein the thickness of the conductivity enhancement layer is in the range of 3 nm to 7 nm.

9. The three-dimensional resistive switching memory device of the claim 1, wherein the variable resistance layer is aluminum oxide (AlOₓ), zirconium oxide (ZrOₓ), titanium oxide (TiOx), niobium oxide (NbOx), nickel oxide (NiOx), zinc oxide (ZnOx), manganeseoxide (MnOₓ), tungsten oxide (WOₓ), tantalum oxide (TaOₓ) or hafnium oxide (HfOₓ).

10. The three-dimensional resistive switching memory device of the claim 1, wherein the resistance of the variable resistance layer is adjusted since oxygen vacancy filaments are formed or destroyed inside the variable resistance layer according to an electric field.

11. The three-dimensional resistive switching memory device of the claim 1, wherein the semiconductor channel layer and the variable resistance layer are connected in parallel for each of the plurality of memory cells.

12. The three-dimensional resistive switching memory device of the claim 11, wherein a piece of information is stored by applying a turn-off voltage to a gate electrode of a selected memory cell among the plurality of memory cells; applying a turn-on voltage to gate electrodes of non-selected memory cells of the plurality of memory cells; changing a current signal flowing through the semiconductor channel layer and the variable resistance layer which are connected in parallel; and changing the magnitude of the resistance of the variable resistance layer of the selected memory cell.

13. The three-dimensional resistive switching memory device of the claim 5, wherein the dual channel layer including the variable resistance layer and the semiconductor channel layer, and the conductivity enhancement layer are connected in parallel.

14. The three-dimensional resistive switching memory device of the claim 13, wherein a turn-off voltage is applied to a gate electrode of a selected memory cell among the plurality of memory cells, and a turn-on voltage is applied to a gate electrode of non-selected memory cells of the plurality of memory cells, and
wherein a piece of information is stored by changing the current signal flowing in the dual channel layer and the variable resistance layer connected in parallel, and changing a magnitude of the resistance of the variable resistance layer of the selected memory cell, while the current flows through the dual channel layer in the unselected memory cells to which the turn-off voltage is applied, and the electric charges of the conductivity enhancement layer moves to the semiconductor channel layer in the selected memory cell to which the turn-off voltage is applied, and thus, the resistance of the dual channel layer is increasing.

15. A method of fabricating a three-dimensional resistive switching memory device comprises,
a step for providing a substrate;
a step for repeatedly and alternately stacking an insulating film and a sacrificial film on the substrate;
a step for forming first holes which are spaced apart from each other in a first direction parallel to the substrate and in a second direction different from the first direction and parallel to the substrate together with the first direction, and which are continuously and vertically penetrating through the repeatedly and alternately laminated the insulating film and the sacrificial film;
a step for forming a gate insulating film having a metal oxide on the inner sidewalls of the holes penetrating the repeatedly and alternately the laminated insulating film and the sacrificial film;
a step for forming a variable resistance layer on the semiconductor channel layer;
a step for forming a trench layer extended in the first direction and a vertical direction by patterning the repeatedly laminated insulating layer and sacrificial layer in order to separate the semiconductor channel layers aligned in the second direction which is parallel to the substrate, thereby forming a laminated structure of an insulating film pattern and a sacrificial film pattern through which the semiconductor channel layers pass;
a step for removing the sacrificial film pattern of the laminated structure exposed through the trench region to form cell spaces where the upper surface of the semiconductor channel layers is exposed between the laminated insulating layer patterns;
a step for forming a gate insulating film on the upper surface of the semiconductor channel layers exposed through the cell spaces; and
a step for forming a conductive layer filling at least a portion of the cell spaces on which the gate insulating layer is formed.

16. The method of fabricating a three-dimensional resistive switching memory device of the claim 15, wherein the semiconductor channel layer is formed by using In₂Ga₂ZnO₇ as a precursor.

17. The method of fabricating a three-dimensional resistive switching memory device of the claim 15, further comprising a step for forming a conductivity enhancement layer after forming the first holes.

18. A method of fabricating a three-dimensional resistive switching memory device comprises,
a step for providing a substrate;
a step for repeatedly and alternately stacking an insulating film and a conductive film on the substrate;
a step for forming first holes which are spaced apart from each other in a first direction parallel to the substrate, and in a second direction different from the first direction and parallel to the substrate together with the first direction, and which are continuously and vertically penetrating the repeatedly and alternately laminated insulating film and conductive film;
a step for forming a gate insulating film on inner sidewalls of the holes passing through the repeatedly and alternately laminated insulating film and conductive film;
a step for forming a semiconductor channel layer including a metal oxide on the gate insulating film; and
a step for forming a variable resistance layer on the semiconductor channel layer.

19. The method of fabricating a three-dimensional resistive switching memory device of the claim 18, wherein the semiconductor channel layer is formed by using In₂Ga₂ZnO₇ as a precursor.

20. The method of fabricating a three-dimensional resistive switching memory device of the claim 18, further comprising a step for forming a conductivity enhancement layer after forming a gate insulating film on the inner sidewalls of the holes penetrating the conductive film.
